(19) United States
(12) Patent Application Publication
(10) Pub. No.: US 2025/0374735 A1
(43) Pub. Date: Dec. 4, 2025

(54) DISPLAY DEVICE AND ELECTRONIC DEVICE

(71) Applicant: Samsung Display Co., LTD., Yongin-si (KR)

(72) Inventors: Hyang A PARK, Yongin-si (KR); Gun Hee KIM, Yongin-si (KR); Tae Kyung AHN, Yongin-si (KR); Byung Han YOO, Yongin-si (KR); Soo Yeong HONG, Yongin-si (KR)

(21) Appl. No.: 19/074,776

(22) Filed: Mar. 10, 2025

(30) Foreign Application Priority Data
May 29, 2024 (KR) 10-2024-0069925

(51) Int. Cl. H10H 29/49

(52) U.S. Cl. CPC H10H 29/49

(57) ABSTRACT

A display device includes a substrate including a display area including a first area and a second area, and a non-display area, first signal lines disposed on the first area and the second area of the substrate, first connection lines extending from the first area to the second area, where each of the first connection lines is electrically connected to a corresponding one of first signal lines disposed in the second area, second connection lines disposed in the first area, where each of the second connection lines is electrically connected to a corresponding one of the first connection lines, and shielding electrodes disposed between the first signal lines and the first connection lines.

This application claims priority to Korean Patent Application No. 10-2024-0069925, filed on May 29, 2024, and all the benefits accruing therefrom under 35 U.S.C. § 119, the content of which in its entirety is herein incorporated by reference.

### BACKGROUND

### 1. Field

The disclosure relates to a display device and an electronic device.

### 2. Description of the Related Art

Recently, as interest in an information display is increasing, research and development for a display device are continuously being conducted.

### SUMMARY

Embodiments of the disclosure provide a display device with improved reliability.

According to an embodiment of the disclosure for solving an object, a display device includes a substrate including a display area including a first area and a second area, and a non-display area, first signal lines disposed on the first area and the second area of the substrate, first connection lines extending from the first area to the second area, where each of the first connection lines is electrically connected to a corresponding one of the first signal lines disposed in the second area, second connection lines disposed in the first area, where each of the second connection lines is electrically connected to a corresponding one of the first connection lines, and shielding electrodes disposed between the first signal lines and the first connection lines.

In an embodiment, the first connection lines may be disposed between the substrate and the first signal lines.

In an embodiment, the first signal lines and the second connection lines may be disposed in a same layer as each other.

In an embodiment, the shielding electrodes may overlap the first signal lines, respectively, in a thickness direction of the substrate.

In an embodiment, the first connection lines may extend in a first direction, and the second connection lines may extend in a second direction crossing the first direction.

In an embodiment, the first signal lines may extend in the second direction.

In an embodiment, the shielding electrodes may extend in the second direction.

In an embodiment, the display device may further include second signal lines spaced apart from the first signal lines.

In an embodiment, the display device may further include first bridge lines extending from the second area to the first area, where each of the first bridge lines may be electrically connected to a corresponding one of the second signal lines disposed in the first area.

In an embodiment, the display device may further include second bridge lines disposed in the second area, where each of the second bridge lines may be electrically connected to a corresponding one of the first bridge lines.

According to an embodiment of the disclosure for solving an object, a display device includes a substrate including a display area including a first area and a second area, and a non-display area, first signal lines disposed on the first area and the second area of the substrate, second signal lines disposed on the first area and the second area of the substrate and spaced apart from the first signal lines, first connection lines extending from the first area to the second area, where each of the first connection lines is electrically connected to at least a corresponding one of the first signal lines disposed in the second area, and second connection lines disposed in the first area, where each of the second connection lines is electrically connected to a corresponding one of the first connection lines. In such an embodiment, the first signal lines are defined by portions of a first conductive layer, the second signal lines are defined by portions of a second conductive layer, and shielding electrodes are disposed between the first conductive layer and the second conductive layer.

In an embodiment, the second connection lines may be defined by portions of the first conductive layer.

In an embodiment, the second connection lines may be defined by portions of the second conductive layer.

In an embodiment, the first connection lines may be defined by portions of a third conductive layer disposed on the first conductive layer and the second conductive layer.

In an embodiment, the first connection lines may extend in a first direction, and the second connection lines may extend in a second direction crossing the first direction.

In an embodiment, the first signal lines and the second signal lines may extend in the second direction.

In an embodiment, the shielding electrodes may extend in the second direction.

In an embodiment, the display device may further include first bridge lines extending from the second area to the first area, wherein each of the first bridge lines may be electrically connected to a corresponding one of the second signal lines disposed in the first area.

In an embodiment, the display device may further include second bridge lines disposed in the second area, where each of the second bridge lines may be electrically connected to a corresponding one of the first bridge lines.

In an embodiment, the display device may further include sub-pixels disposed in the display area and including a light emitting element which emits light, and light sensing pixels including a light receiving element which outputs a sensing signal corresponding to the light.

According to an embodiment of the disclosure for solving an object, an electronic device includes a processor to provide input image data; and a display device to display an image based on the input image data, the display device including sub-pixel areas, wherein the display device comprises a substrate including a display area including a first area and a second area, and a non-display area, first signal lines disposed on the first area and the second area of the substrate, first connection lines extending from the first area to the second area, where each of the first connection lines is electrically connected to a corresponding one of the first signal lines disposed in the second area, second connection lines disposed in the first area, where each of the second connection lines is electrically connected to a corresponding one of the first connection lines, and shielding electrodes disposed between the first signal lines and the first connection lines.

According to embodiments described herein, by providing shielding electrodes between readout lines (or data lines) and horizontal connection lines (or horizontal bridge lines), which overlap or cross each other, a coupling cap that may occur due to overlapping lines may be minimized and crosstalk may be improved, thereby improving reliability of the display device.

An effect according to embodiments is not limited by the contents illustrated above, and more various effects are included in the specification.

### BRIEF DESCRIPTION OF THE DRAWINGS

The above and other features of the disclosure will become more apparent by describing in further detail embodiments thereof with reference to the accompanying drawings, in which:

FIGS. 1 and 2 are plan views schematically illustrating a display device according to an embodiment;

FIG. 3 is a cross-sectional view schematically illustrating a display device according to an embodiment;

FIG. 4 is a circuit diagram schematically illustrating a sub-pixel and a light sensing pixel according to an embodiment;

FIG. 5 is a cross-sectional view schematically illustrating one area of a display device according to an embodiment;

FIG. 6 is a cross-sectional view schematically illustrating a reflection path of light in the display device of FIG. 5;

FIG. 7 is a plan view schematically illustrating a data line, a readout line, a bridge line, a connection line, a first line, and a second line of the display device of FIG. 1;

FIG. 8 is an enlarged plan view schematically illustrating an area EA of FIG. 7;

FIGS. 9, 11, 13, 15, 17, 19, 21, 23, 25, 27, 29, and 31 are cross-sectional views taken along line I-I′ of FIG. 8, illustrating a display device according to various embodiments; and

FIGS. 10, 12, 14, 16, 18, 20, 22, 24, 26, 28, 30, and 32 are cross-sectional views taken along line II-II′ of FIG. 8, illustrating a display device according to various embodiments.

FIG. 33 is a schematic block diagram illustrating an electronic device including a display device in accordance with an embodiment.

FIG. 34 is a schematic diagram illustrating an example where the electronic device of FIG. 33 is a smartphone.

FIG. 35 is a schematic diagram illustrating an example where the electronic device of FIG. 33 is a tablet computer.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The term “coupling” or “connection” may collectively mean a physical and/or electrical coupling or connection. This may collectively mean a direct or indirect coupling or connection and an integral or non-integral coupling or connection.

It will be understood that when an element is referred to as being “on” another element, it can be directly on the other element or intervening elements may be present therebetween. In contrast, when an element is referred to as being “directly on” another element, there are no intervening elements present.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

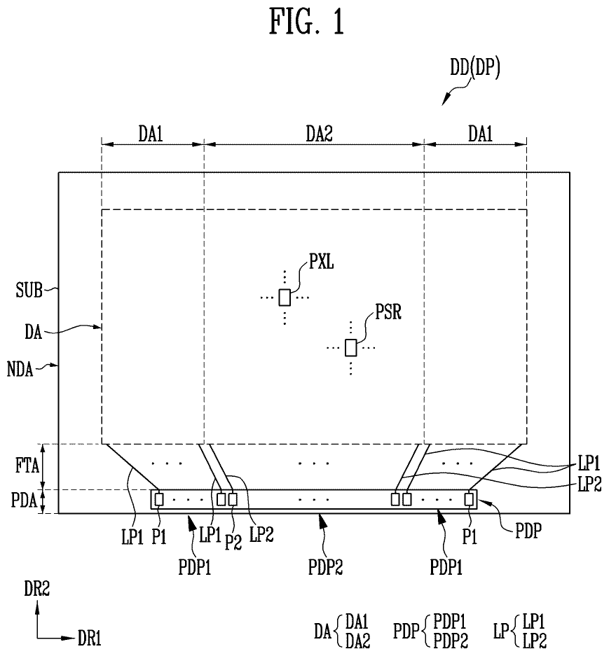

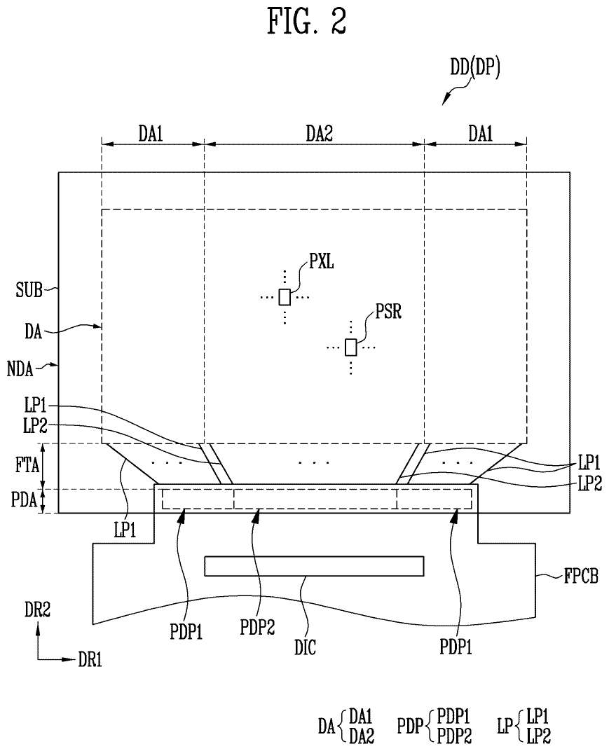

FIGS. 1 and 2 are plan views schematically illustrating a display device according to an embodiment.

In FIGS. 1 and 2, for convenience of illustration and description, a structure of the display device DD, for example, a display panel DP provided in the display device DD, is schematically shown based on a display area DA where an image is displayed.

Referring to FIGS. 1 and 2, an embodiment of the display device DD (or the display panel DP) may include a substrate SUB, sub-pixels PXL, and/or light sensing pixels PSR.

The display device DD may be provided in various shapes. In an embodiment, for example, the display device DD may be provided in a rectangular plate shape having two pairs of sides parallel to each other, but is not limited thereto. Embodiments disclosed herein may be applied when the display device DD is an electronic device in which a display surface is defined in at least one surface thereof, such as a smartphone, a television, a tablet personal computer (PC), a mobile phone, a video phone, an e-book reader, a desktop PC, a laptop PC, a netbook computer, a workstation, a server, a personal digital assistant (PDA), a portable multimedia player (PMP), an MP3 player, a medical device, a camera, or a wearable.

The substrate SUB may include a transparent insulating material, and thus light may be transmitted therethrough. The substrate SUB may be a rigid substrate or a flexible substrate.

The rigid substrate may include (or be defined by) at least one selected from a glass substrate, a quartz substrate, a glass ceramic substrate, and a crystalline glass substrate.

The flexible substrate may include (or be defined by) at least one selected from a film substrate and a plastic substrate including a polymeric organic material. In an embodiment, for example, the flexible substrate may include at least one selected from polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, triacetate cellulose, and cellulose acetate propionate, but is not necessarily limited thereto.

One area of the substrate SUB may be provided as the display area DA, and thus sub-pixels PXL and light sensing pixels PSR may be disposed in the one area. A remaining area of the substrate SUB may be provided as a non-display area NDA.

In an embodiment, the display area DA may include a first area DA1 and a second area DA2. The first area DA1 may be positioned on both opposing sides of the second area DA2. In an embodiment, for example, the second area DA2 may be positioned at a center of the substrate SUB (or the display device DD), and the first area DA1 may be positioned at an edge of the substrate SUB. The second area DA2 may be positioned on an inside, and the first area DA1 may be positioned on an outside, but the disclosure is not necessarily limited thereto.

The first area DA1 may be one area of the display area DA corresponding to a first line LP1 of a line unit LP, and the second area DA2 may be one area of the display device DA corresponding to a second line LP2 of the line unit LP.

The first area DA1 may be adjacent to one area of the non-display area NDA where the first line LP1 is positioned, and the second area DA2 may be adjacent to one area of the non-display area NDA where the second line LP2 is positioned.

The sub-pixels PXL and the light sensing pixels PSR may be disposed in the first area DA1 and the second area DA2.

The sub-pixels PXL may include a light emitting element including a light emitting layer. According to an embodiment, the light emitting element may include an organic light emitting diode or an inorganic light emitting diode having a size of a range from micrometer to nanometer, but is not limited thereto. The display device DD may display an image in the first area DA1 and the second area DA2 by driving the sub-pixels PXL correspondingly to input image data.

The display area DA may include a sensing area capable of sensing a user's fingerprint or the like. In an embodiment, for example, the first area DA1 and the second area DA2 may be set as a sensing area capable of sensing a user's fingerprint or the like. In an embodiment where the entire display area DA is set as the sensing area, the non-display area NDA surrounding the display area DA may become a non-sensing area.

Light sensing pixels PSR (or a light sensor) may be disposed in the first area DA1 and the second area DA2. The light sensing pixels PSR may include a light receiving element including a light receiving layer. In the first area DA1 and the second area DA2, the light receiving layer of the light receiving element may be disposed to be spaced apart from a light emitting layer of a light emitting element.

The light sensing pixels PSR may sense the light emitted from a light source (for example, the light emitting element) and then reflected by an external object (for example, a user's finger or the like). In an embodiment, for example, a user's fingerprint may be sensed through the light sensing pixels PSR. Hereinafter, embodiments where the light sensing pixels PSR are used for fingerprint sensing will be mainly described as an example, but in various embodiments, the light sensing pixels PSR may sense various biometric information such as iris, a vein, or the like. In addition, the light sensing pixels PSR may sense external light and may perform a function of a gesture sensor, a motion sensor, a proximity sensor, an illumination sensor, an image sensor, and/or the like.

In the non-display area NDA, the line unit LP, a pad unit PDP, and/or an internal circuit unit for driving the sub-pixels PXL and the light sensing pixels PSR may be disposed. The non-display area NDA may include a fan-out area FTA and a pad area PDA.

The pad area PDA may be one area of the non-display area NDA where the pad unit PDP is positioned, and may be positioned at an edge of the non-display area NDA.

The fan-out area FTA may be one area of the non-display area NDA where the line unit LP is positioned, and may be positioned between the display area DA and the pad area PDA in the non-display area NDA.

According to an embodiment, the non-display area NDA may include an anti-static circuit area where an anti-static circuit electrically connected to signal lines positioned in the display area DA to prevent generation of static electricity is positioned.

The line unit LP may be positioned in the fan-out area FTA, and the pad unit PDP may be positioned in the pad area PDA.

The line unit LP may be electrically connected to the sub-pixels PXL and the light sensing pixels PSR and may transmit a predetermined signal applied from a driver DIC to signal lines. The line unit LP may include fan-out lines electrically connecting the driver DIC and the sub-pixels PXL to each other, and fan-out lines electrically connecting the driver DIC and the light sensing pixels PSR to each other.

The line unit LP may include a first line LP1 and a second line LP2. In the fan-out area FTA, the first line LP1 may be positioned on both sides of the second line LP2. In an embodiment, for example, the second line LP2 may be positioned at a center of the fan-out area FTA to correspond to the second area DA2, and the first line LP1 may be positioned at an edge of the fan-out area FTA to correspond to the first area DA1. The second line LP2 may be positioned on an inside in the fan-out area FTA, and the first line LP1 may be positioned on an outside in fan-out area FTA. Accordingly, the first line LP1 and the second line LP2 may be separated in the fan-out area FTA.

The first line LP1 may be disposed in one area of the fan-out area FTA positioned between the first area DA1 and the pad unit PDP. The first line LP1 may be provided in plural and may include fan-out lines electrically connected to the light sensing pixels PSR positioned in the first area DA1. In an embodiment, for example, the first line LP1 may include the fan-out lines electrically connected to a readout line (or a first signal line) connected to the light sensing pixels PSR positioned in the first area DA1 for transmitting an electrical signal (for example, a sensing signal) received from the light sensing pixels PSR to the driver DIC.

In an embodiment, the first line LP1 may include the fan-out lines electrically connected to the readout line connected to the light sensing pixels PSR positioned in the second area DA2 through a connection line extending from the first area DA1 to the second area DA2.

The second line LP2 may be disposed in one area of the fan-out area FTA positioned between the second area DA2 and the pad unit PDP. The second line LP2 may be provided in plural and may include fan-out lines electrically connected to the sub-pixels PXL positioned in the second area DA2. In an embodiment, for example, the second line LP2 may include the fan-out lines electrically connected to a data line (or a second signal line) connected to the sub-pixels PXL positioned in the second area DA2 for transmitting a data signal to the sub-pixels PXL.

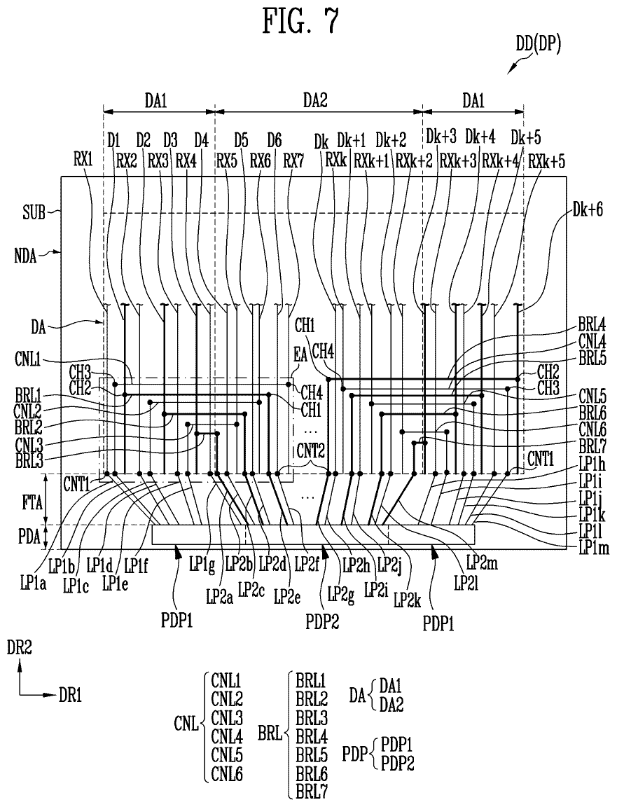

In an embodiment, the second line LP2 may include fan-out lines electrically connected the data line connected to the sub-pixels PXL positioned in the first area DA1 through a bridge line (e.g., the bridge line BL shown in FIG. 7) extending from the second area DA2 to the first area DA1.

The pad unit PDP may be disposed in the pad area PDA and may supply driving power and signals for driving the sub-pixels PXL and the light sensing pixels PSR disposed in the display area DA. The pad unit PDP may be electrically connected to the line unit LP. In an embodiment, the pad unit PDP may include a first pad unit PDP1 and a second pad unit PDP2.

In the pad area PDA, the first pad unit PDP1 may be positioned on both opposing sides of the second pad unit PDP2. In an embodiment, for example, the second pad unit PDP2 may be positioned at a center of the pad area PDA to correspond to the second line LP2, and the first pad unit PDP1 may be positioned at an edge of the pad area PDA to correspond to the first line LP1. The second pad unit PDP2 may be positioned on an inside in the pad area PDA, and the first pad unit PDP1 may be positioned on an outside in the pad area PDA, but the disclosure is not necessarily limited thereto.

The first pad unit PDP1 may include a first pad P1 electrically connected to the first line LP1, and the second pad unit PDP2 may include a second pad P2 electrically connected to the second line LP2.

The first pad P1 may be provided in plural. The first pad P1 may be electrically connected to the readout line connected to the light sensing pixels PSR positioned in the first area DA1 through the corresponding first line LP1. The first pad P1 may be electrically connected to the connection line through the corresponding first line LP1.

The second pad P2 may be provided in plural. The second pad P2 may be electrically connected to the data line connected to the sub-pixels PXL positioned in the second area DA2 through the corresponding second line LP2. In addition, the second pad P2 may be electrically connected to the bridge line through the corresponding second line LP2.

In an embodiment, as shown in FIG. 2, the display device DD may include a circuit board FPCB connected to the display panel DP through the pad unit PDP. The circuit board FPCB may be a flexible circuit board, but is not limited thereto.

The circuit board FPCB may process various signals input thereto from a printed circuit board and output the processed various signals to the display panel DP. One end of the circuit board FPCB may be attached to the display panel DP, and another end of the circuit board FPCB may be attached to the printed circuit board. The circuit board FPCB may be connected to each of the display panel DP and the printed circuit board by a conductive adhesive member (for example, an anisotropic conductive film).

The driver DIC may be mounted on the circuit board FPCB. In an embodiment, for example, the driver DIC may be an integrated circuit (IC). The driver DIC may include a panel driver and a fingerprint detector.

The panel driver may sequentially scan the sub-pixels PXL and supply a data signal corresponding to an image data signal to the sub-pixels PXL. The display panel DP may display an image corresponding to the image data signal. The panel driver may supply a driving signal for fingerprint sensing to the sub-pixels PXL. The driving signal may be provided to cause the sub-pixels PXL to emit light and operate as a light source for the light sensing pixels PSR. In an embodiment, the panel driver may also supply the driving signal for the fingerprint sensing and/or another driving signal to the light sensing pixels PSR. However, the disclosure is not limited thereto, and the driving signals for the fingerprint sensing may be provided by the fingerprint detector.

The fingerprint detector may detect biometric information such as the user's fingerprint based on a sensing signal received from the light sensing pixels PSR. The fingerprint detector may supply the driving signals to the light sensing pixels PSR and/or the sub-pixels PXL.

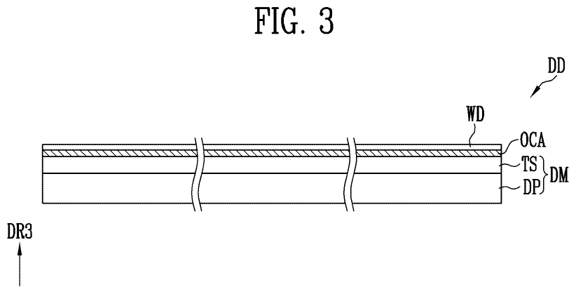

FIG. 3 is a cross-sectional view schematically illustrating a display device according to an embodiment.

Referring to FIG. 3, an embodiment of the display device DD may include a display module DM and a window WD.

The display module DM may include the display panel DP and a touch sensor TS.

The touch sensor TS may be directly disposed on the display panel DP, or may be disposed on the display panel DP with a separate layer such as an adhesive layer or a substrate (or an insulating layer) interposed therebetween.

The display panel DP may display an image. As the display panel DP, a display panel capable of self-emitting, such as an organic light emitting display panel (OLED) panel, may be used. As the display panel DP, non-emitting display panel, such as a liquid crystal display panel (LCD panel), an electrophoretic display panel (EPD panel), and an electrowetting display panel (EWD panel), may be used. In an embodiment where the non-emitting display panel is used as the display panel DP, the display device DD may include a backlight unit that provides light to the display panel DP.

The touch sensor TS may be disposed on a surface through which an image is emitted of the display panel DP and may receive a user's touch input. The touch sensor TS may detect a touch event of the display device DD through a user's hand or a separate input means. The touch sensor TS may detect the touch event in a capacitance method.

The touch sensor TS may sense the touch input in a mutual capacitance method or a self capacitance method.

The window WD (or a cover glass) for protecting an exposed surface of the display module DM may be provided on the display module DM. The window WD may protect the display module DM from external shock and provide an input surface and/or a display surface to a user. The window WD may be combined with the display module DM using an optically transparent adhesive member OCA.

The window WD may have a multilayer structure and may include at least one selected from a glass substrate, a plastic film, and a plastic substrate. The multilayer structure may be formed through a continuous process or an adhesion process using an adhesive layer. The entire or a portion of the window WD may have flexibility.

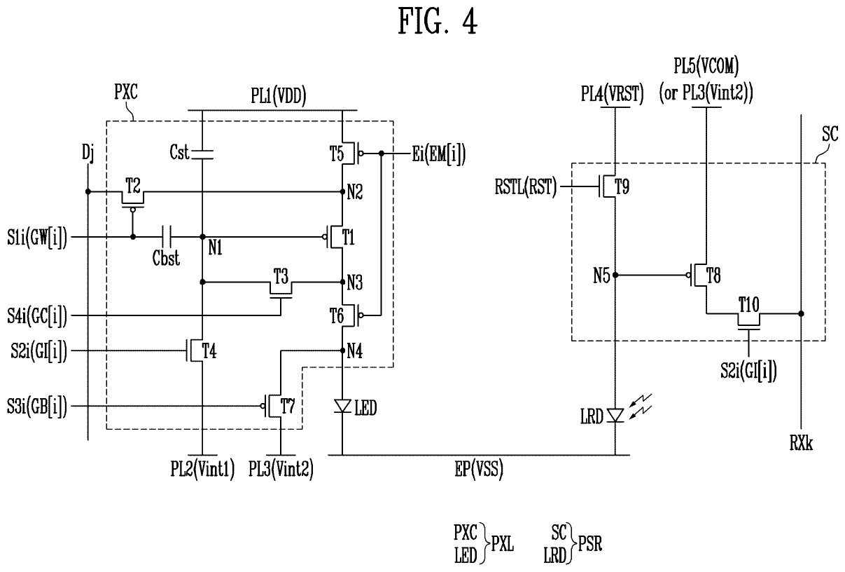

FIG. 4 is a circuit diagram schematically illustrating a sub-pixel and a light sensing pixel according to an embodiment.

For convenience of illustration and description, FIG. 4 shows a sub-pixel PXL positioned in an i-th horizontal line (or an i-th pixel row) and connected to a j-th data line Dj. Here, i and j are natural numbers.

Referring to FIG. 4, the sub-pixel PXL and the light sensing pixel PSR may be disposed in the i-th horizontal line.

The sub-pixel PXL may include a light emitting element LED and a pixel circuit PXC connected to the light emitting element LED. In an embodiment, the pixel circuit PXC may include first to seventh transistors T1, T2, T3, T4, T5, T6, and T7, a storage capacitor Cst, and/or a boost capacitor Cbst.

The first transistor T1 (or a driving transistor) may be electrically connected between a first power line PL1 and a first electrode of the light emitting element LED. The first transistor T1 may include a gate electrode electrically connected to a first node N1. The first transistor T1 may control a current amount (or a driving current) flowing from the first power line PL1 to an electrode EP (or a power line) via the light emitting element LED based on a voltage of the first node N1. A first power voltage VDD may be provided to the first power line PL1, a second power voltage VSS may be provided to the electrode EP, and the first power voltage VDD may be set to a voltage higher than the second power voltage VSS.

The second transistor T2 may be electrically connected between the j-th data line Dj and a second node N2. A gate electrode of the second transistor T2 may be connected to a 1i-th scan line (or a first i-th scan line). The second transistor T2 may be turned on when a first scan signal GW[i] (for example, a low level of first scan signal) is supplied to the 1i-th scan line S1i to electrically connect the j-th data line Dj and the second node N2. When each of the first transistor T1 and the third transistor T3 is turned on, the second transistor T2 may transmit a data signal of the j-th data line Dj to the first node N1 in response to the first scan signal GW[i].

The third transistor T3 may be electrically connected between the first node N1 and a third node N3. A gate electrode of the third transistor T3 may be electrically connected to a 4i-th scan line S4i (or a fourth i-th scan line). A third transistor T3 may be turned on when a fourth scan signal GC[i] is supplied to the 4i-th scan line S4i. When the third transistor T3 is turned on, the first transistor T1 may have a diode-connected form.

The fourth transistor T4 may be electrically connected between the first node N1 and a second power line PL2. A gate electrode of the fourth transistor T4 may be electrically connected to a 2i-th scan line S2i (or a second i-th scan line). A first initialization power voltage Vint1 may be provided to the second power line PL2. The fourth transistor T4 may be turned on by a second scan signal GI[i] supplied to the 2i-th scan line S2i. When the fourth transistor T4 is turned on, the first initialization power voltage Vint1 may be supplied to the first node N1 (that is, the gate electrode of the first transistor T1).

The fifth transistor T5 may be electrically connected between the first power line PL1 and the second node N2. A gate electrode of the fifth transistor T5 may be electrically connected to an i-th emission control line Ei. The sixth transistor T6 may be electrically connected between the third node N3 and the light emitting element LED (or a fourth node N4). A gate electrode of the sixth transistor T6 may be electrically connected to the i-th emission control line Ei. The fifth transistor T5 and the sixth transistor T6 may be turned off when an emission control signal EM[i] (for example, a high level of emission control signal EM[i]) is supplied to the i-th emission control line Ei, and may be turned on in other cases.

The seventh transistor T7 may be electrically connected between a first electrode (that is, the fourth node N4) of the light emitting element LED and a third power line PL3. A gate electrode of the seventh transistor T7 may be electrically connected to a 3i-th scan line S3i (or a third i-th scan line). A second initialization power voltage Vint2 may be provided to the third power line PL3. According to an embodiment, the second initialization power voltage Vint2 may be different from the first initialization power voltage Vint1. The seventh transistor T7 may be turned on by a third scan signal GB[i] supplied to the 3i-th scan line S3i to supply the second initialization power voltage Vint2 to the first electrode of the light emitting element LED.

The storage capacitor Cst may be connected or formed between the first power line PL1 and the first node N1.

The boost capacitor Cbst may be connected or formed between the gate electrode of the second transistor T2 and the gate electrode of the first transistor T1.

The light sensing pixel PSR may include a sensor circuit SC and a light receiving element LRD. The sensor circuit SC may include eighth to tenth transistors T8, T9, and T10.

The eighth transistor T8 and the tenth transistor T10 may be connected in series between a fifth power line PL5 and a k-th readout line RXk (where k is a positive integer).

The eighth transistor T8 (or a first sensor transistor) may be electrically connected between the fifth power line PL5 and the tenth transistor T10. A gate electrode of the eighth transistor T8 may be electrically connected to a fifth node N5 (or a sensor node). The eighth transistor T8 may control a current flowing from the fifth power line PL5 to the k-th readout line RXk through the tenth transistor T10 in response to a voltage of the fifth node N5. A common voltage VCOM may be provided to the fifth power line PL5.

In an embodiment, the fifth power line PL5 may be electrically connected to the third power line PL3 or integrally formed with the third power line PL3. The common voltage VCOM applied to the fifth power line PL5 may be the same as the second initialization power voltage Vint2, but is not limited thereto. According to an embodiment, the fifth power line PL5 may be electrically connected to the second power line PL2 or integrally formed with the second power line PL2. The common voltage VCOM applied to the fifth power line PL5 may be the same as the first initialization power voltage Vint1, but is not limited thereto.

The tenth transistor T10 (a second sensor transistor, or a switching transistor) may be electrically connected between the eighth transistor T8 and the k-th readout line RXk. Here, k is a natural number. A gate electrode of the tenth transistor T10 may be electrically connected to the 2i-th scan line S2i. A gate electrode of the tenth transistor T10 and the gate electrode of the fourth transistor T4 may share the 2i-th scan line S2i.

The ninth transistor T9 (or a third sensor transistor) may be electrically connected between a fourth power line PL4 (or a reference power line) and the fifth node N5. A gate electrode of the ninth transistor T9 may be electrically connected to a reset control line RSTL. A reset voltage VRST may be provided to the fourth power line PL4. The reset voltage VRST may be a direct current voltage having a constant level.

At least one light receiving element LRD may be electrically connected between the fifth node N5 and the electrode EP to which the second power voltage VSS is provided.

The light receiving element LRD may perform a function of photoelectric conversion. In an embodiment, for example, the light receiving element LRD may generate a charge (or a current) based on incident light. The light receiving element LRD may be implemented as a photo diode.

When the ninth transistor T9 is turned on by a reset signal RST supplied to the reset control line RSTL, the reset voltage VRST may be supplied to the fifth node N5. In an embodiment, for example, a voltage of the fifth node N5 may be reset by the reset voltage VRST. After the reset voltage VRST is applied to the fifth node N5, the light receiving element LRD may perform a function of photoelectric conversion.

The voltage of the fifth node N5 may change by an operation of the light receiving element LRD. The voltage (or the charge or the current generated in the light receiving element LRD) of the fifth node N5 may change according to an intensity of light incident on the light receiving element LRD and a time when the light is incident (or a time when the light receiving element LRD is exposed to light).

When the tenth transistor T10 is turned on by the second scan signal GI[i] supplied to the 2i-th scan line S2i, a detection value (current and/or voltage) generated based on the voltage of the fifth node N5 may flow to the k-th readout line RXk.

In an embodiment, each of the pixel circuit PXC and the sensor circuit SC may include a P-type transistor and/or an N-type transistor. The third transistor T3, the fourth transistor T4, the ninth transistor T9, and the tenth transistor T10 may include or be formed of an oxide semiconductor transistor including an oxide semiconductor (or a second type semiconductor). In an embodiment, for example, the third transistor T3, the fourth transistor T4, the ninth transistor T9, and the tenth transistor T10 may be N-type oxide semiconductor transistors and include an oxide semiconductor layer as an active layer, but are not limited thereto.

In such an embodiment, the remaining transistors (for example, the first, second, fifth, sixth, seventh, and eighth transistors T1, T2, T5, T6, T7, and T8) may include or be formed of a polysilicon transistor including a silicon semiconductor (or a first type semiconductor) and may include a polysilicon semiconductor layer as an active layer. In an embodiment, for example, the active layer may be formed through a low-temperature polysilicon process.

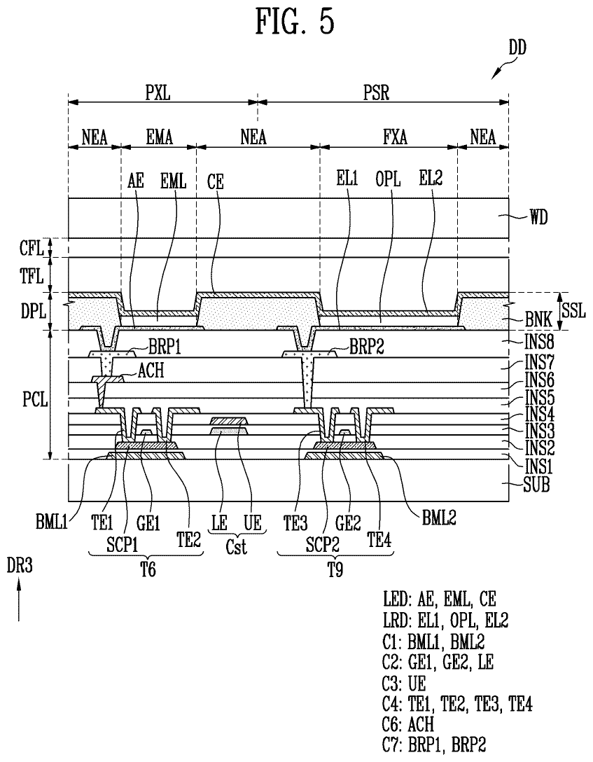

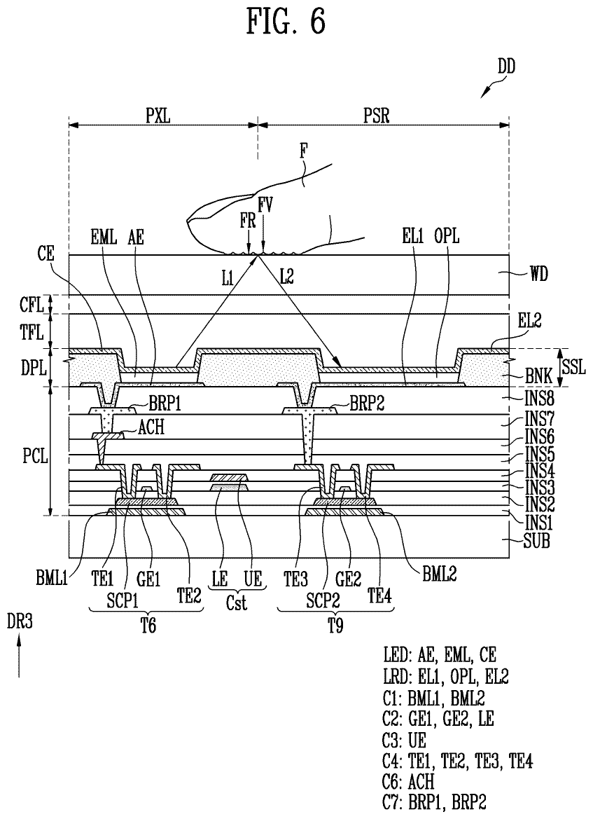

FIG. 5 is a cross-sectional view schematically illustrating one area of a display device according to an embodiment. FIG. 6 is a cross-sectional view schematically illustrating a reflection path of light in the display device of FIG. 5. FIGS. 5 and 6 show a portion of a stack structure (or a cross-sectional structure) of the sub-pixel PXL including the light emitting element LED and the light sensing pixel PSR including the light receiving device LRD, and show a cross-section of the sixth transistor T6 among the first to seventh transistors T1, T2, T3, T4, T5, T6, and T7 and the ninth transistor T9 among the eighth to tenth transistors T8, T9, and T10 of FIG. 4.

Referring to FIGS. 5 and 6, an embodiment of the display device DD may include the sub-pixel PXL and the light sensing pixel PSR disposed on the substrate SUB.

A pixel circuit layer PCL of the sub-pixel PXL and a pixel circuit layer PCL of the light sensing pixel PSR may be disposed on the substrate SUB. The pixel circuit layer PCL may include first to eighth insulating layers INS1, INS2, INS3, INS4, INS5, INS6, INS7, and INS8 sequentially stacked on the substrate SUB along a third direction DR3, which is a thickness direction of the display device DD or the substrate SUB.

The first insulating layer INS1 (or a buffer layer) may be entirely disposed on the substrate SUB. The first insulating layer INS1 may effectively prevent an impurity from diffusing into the sixth transistor T6 and the ninth transistor T9. The first insulating layer INS1 may be an inorganic layer including an inorganic material (or substance). The first insulating layer INS1 may include at least one selected from silicon nitride (SiNx), silicon oxide (SiOx), silicon oxynitride (SiOxNy), and aluminum oxide (AIOx). The first insulating layer INS1 may be provided as a single layer, but may also be provided as a multilayer of at least a double layer or more. The first insulating layer INS1 may be omitted according to a material, a process condition, and the like of the substrate SUB.

The second insulating layer INS2 (or a first gate insulating layer) may be entirely disposed on the first insulating layer INS1. The second insulating layer INS2 may include a same material as the first insulating layer INS1 or may include a suitable (or selected) material among the materials exemplified as a configuration material of the first insulating layer INS1. In an embodiment, for example, the second insulating layer INS2 may be an inorganic layer including an inorganic material.

The third insulating layer INS3 (or a second gate insulating layer) may be entirely disposed on the second insulating layer INS2. The third insulating layer INS3 may include the same material as the first insulating layer INS1 or may include one or more suitable (or selected) materials among the materials listed above as a configuration material of the first insulating layer INS1.

The fourth insulating layer INS4 (or an interlayer insulating layer) may be entirely disposed on the third insulating layer INS3. The fourth insulating layer INS4 may be an inorganic layer including an inorganic material or an organic layer including an organic material.

The fifth insulating layer INS5 (or a passivation layer) may be entirely disposed on the fourth insulating layer INS4. The fifth insulating layer INS5 may be an inorganic layer including an inorganic material or an organic layer including an organic material.

The sixth insulating layer INS6 (or a first via layer) may be entirely disposed on the fifth insulating layer INS5. The sixth insulating layer INS6 may be an inorganic layer including an inorganic material or an organic layer including an organic material. The inorganic layer may include at least one selected from silicon oxide (SiOx), silicon nitride (SiNx), silicon oxynitride (SiOxNy), and aluminum oxide (AIOx). The organic layer may include at least one selected from acrylic resin (polyacrylates resin), epoxy resin, phenolic resin, polyamides resin, polyimides resin, unsaturated polyesters resin, polyphenylene ethers resin, polyphenylene sulfides resin, and benzocyclobutene resin.

The seventh insulating layer INS7 (or a second via layer) may be entirely disposed on the sixth insulating layer INS6. The seventh insulating layer INS7 may include a same material as the sixth insulating layer INS6 or may include one or more suitable (or selected) materials among the materials listed above as a configuration material of the sixth insulating layer INS6. In an embodiment, for example, the seventh insulating layer INS7 may be an organic layer including an organic material.

The eighth insulating layer INS8 (or a third via layer) may be entirely disposed on the seventh insulating layer INS7. The eighth insulating layer INS8 may include a same material as the sixth insulating layer INS6 or may include one or more suitable (or selected) materials among the materials listed above as a configuration material of the sixth insulating layer INS6. In an embodiment, for example, the eighth insulating layer INS8 may be an organic layer including an organic material.

The pixel circuit layer PCL may include at least one or more conductive layers disposed between the above-described insulating layers. In an embodiment, for example, the conductive layers may include a first conductive layer C1 provided between the substrate SUB and the first insulating layer INS1, a second conductive layer C2 provided on the second insulating layer INS2, a third conductive layer C3 provided on the third insulating layer INS3, a fourth conductive layer C4 provided on the fourth insulating layer INS4, a fifth conductive layer C5 provided on the fifth insulating layer INS5, a sixth conductive layer C6 provided on the sixth insulating layer INS6, and/or a seventh conductive layer C7 provided on the seventh insulating layer INS7. However, the insulating layers and the conductive layers are not limited to those described above, and according to an embodiment, other insulating layers or other conductive layers in addition to the insulating layers and the conductive layers described above may be disposed in the pixel circuit layer PCL.

The sixth transistor T6 and the ninth transistor T9 may be disposed in the pixel circuit layer PCL. The sixth transistor T6 may include a first gate electrode GE1, a first semiconductor pattern SCP1, a first terminal TE1, and a second terminal TE2. The ninth transistor T9 may include a second gate electrode GE2, a second semiconductor pattern SCP2, a third terminal TE3, and a fourth terminal TE4.

The first semiconductor pattern SCP1 and the second semiconductor pattern SCP2 may be disposed on the first insulating layer INS1. The first semiconductor pattern SCP1 may include a polysilicon semiconductor, and the second semiconductor pattern SCP2 may include an oxide semiconductor, but the disclosure is not necessarily limited thereto. Each of the first semiconductor pattern SCP1 and the second semiconductor pattern SCP2 may include a channel area, a first contact area connected to one end of the channel area, and a second contact area connected to another end of the channel area. The first contact area may be a source area and the second contact area may be a drain area. The second insulating layer INS2 may be disposed on the first semiconductor pattern SCP1 and the second semiconductor pattern SCP2.

The first gate electrode GE1 and the second gate electrode GE2 may be configured of (or defined by portions of) the second conductive layer C2 disposed on the second insulating layer INS2. The second conductive layer C2 may be formed as a single layer or multiple layers, each layer therein including or formed of at least one selected from molybdenum (Mo), copper (Cu), chromium (Cr), gold (Au), silver (Ag), titanium (Ti), nickel (Ni), neodymium (Nd), indium (In), tin (Sn), and an oxide or an alloy thereof. In an embodiment, for example, the second conductive layer C2 may be formed of multiple layers of titanium (Ti), copper (Cu), and/or indium tin oxide (ITO) sequentially or repeatedly stacked. The first gate electrode GE1 may overlap one area of the first semiconductor pattern SCP1. The one area of the first semiconductor pattern SCP1 overlapping the first gate electrode GE1 may be the channel area of the sixth transistor T6. The second gate electrode GE2 may overlap one area of the second semiconductor pattern SCP2. The one area of the second semiconductor pattern SCP2 overlapping the second gate electrode GE2 may be the channel area of the ninth transistor T9.

The third insulating layer INS3 may be disposed on the first gate electrode GE1 and the second gate electrode GE2.

The first to fourth terminals TE1, TE2, TE3, and TE4 may be configured of (or defined by a portion of) the fourth conductive layer C4 disposed on the fourth insulating layer INS4. The fourth conductive layer C4 may be formed as a single layer or multiple layers, each layer therein including or formed of at least one selected from molybdenum (Mo), copper (Cu), aluminum (AI), chromium (Cr), gold (Au), silver (Ag), titanium (Ti), nickel (Ni), neodymium (Nd), indium (In), tin (Sn), and an oxide or an alloy thereof.

The first terminal TE1 may be electrically connected to the first contact area of the first semiconductor pattern SCP1 through a contact hole defined or formed through the second to fourth insulating layers INS2, INS3, and INS4. The first terminal TE1 may be electrically connected to an anode electrode AE of the light emitting element LED.

The second terminal TE2 may be electrically connected to the second contact area of the first semiconductor pattern SCP1 through a contact hole defined or formed through the second to fourth insulating layers INS2, INS3, and INS4.

The third terminal TE3 may be electrically connected to the first contact area of the second semiconductor pattern SCP2 through a contact hole defined or formed through the second to fourth insulating layers INS2, INS3, and INS4. The third terminal TE3 may be electrically connected to a first electrode EL1 of the light receiving element LRD.

The fourth terminal TE4 may be electrically connected to the second contact area of the second semiconductor pattern SCP2 through a contact hole defined or formed through the second to fourth insulating layers INS2, INS3, and INS4.

The fifth insulating layer INS5 may be disposed on the first to fourth terminals TE1, TE2, TE3, and TE4.

A first lower metal pattern BML1 and a second lower metal pattern BML2 may be disposed in the pixel circuit layer PCL. The first lower metal pattern BML1 may be configured of (or defined by a portion of) the first conductive layer C1 disposed on the substrate SUB, and may overlap the sixth transistor T6. The second lower metal pattern BML2 may be configured of (or defined by a portion of) the first conductive layer C1 disposed on the substrate SUB and may overlap the ninth transistor T9. According to an embodiment, the first lower metal pattern BML1 may be electrically connected to the sixth transistor T6 to stabilize the channel area of the sixth transistor T6. The second lower metal pattern BML2 may stabilize the channel area of the ninth transistor T9 electrically connected to the ninth transistor T9.

The storage capacitor Cst may be disposed in the pixel circuit layer PCL. The storage capacitor Cst may include a lower electrode LE and an upper electrode UE. The lower electrode LE may be configured of (or defined by a portion of) the second conductive layer C2. The third insulating layer INS3 may be disposed on the lower electrode LE.

The upper electrode UE may be disposed on the third insulating layer INS3. The upper electrode UE may overlap the lower electrode LE with the third insulating layer INS3 therebetween. The upper electrode UE may be configured of (or defined by a portion of) the third conductive layer C3, but is not limited thereto. The upper electrode UE may form a capacitance by overlapping the lower electrode LE with the third insulating layer INS3 therebetween.

An anode connection portion ACH, a first bridge pattern BRP1, and/or a second bridge pattern BRP2 may be disposed in the pixel circuit layer PCL.

The anode connection portion ACH may be configured of (or defined by a portion of) the sixth conductive layer C6 disposed on the sixth insulating layer INS6. The anode connection portion ACH may be electrically connected to the first terminal TE1 through a contact hole defined or formed through the fifth and sixth insulating layers INS5 and INS6. The anode connection portion ACH may include a same material as the second conductive layer C2 or may include a suitable (or selected) material among the materials listed above as a configuration material of the second conductive layer C2. The seventh insulating layer INS7 may be disposed on the anode connection portion ACH.

The first bridge pattern BRP1 and the second bridge pattern BRP2 may be configured of (or defined by a portion of) the seventh conductive layer C7. The first bridge pattern BRP1 and the second bridge pattern BRP2 may be disposed to be spaced apart from each other on the seventh insulating layer INS7. The first bridge pattern BRP1 and the second bridge pattern BRP2 may include a same material as the second conductive layer C2 or may include a suitable (or selected) material among the materials listed above as a configuration material of the second conductive layer C2.

The first bridge pattern BRP1 may be electrically connected to the anode connection portion ACH through a contact hole defined or formed through the seventh insulating layer INS7. The second bridge pattern BRP2 may be electrically connected to the third terminal TE3 through a contact hole defined or formed through the fifth to seventh insulating layers INS5, INS6, and INS7. The eighth insulating layer INS8 may be disposed on the first bridge pattern BRP1 and the second bridge pattern BRP2.

A display element layer DPL may be disposed on the pixel circuit layer PCL of the sub-pixel PXL. A sensor layer SSL may be disposed on the pixel circuit layer PCL of the light sensing pixel PSR.

The light emitting element LED and a bank BNK may be disposed in the display device layer DPL. The light emitting element LED may include an anode electrode AE (or a pixel electrode), a light emitting layer EML, and/or a cathode electrode CE (or a common electrode). The light emitting element LED may be electrically connected to the sixth transistor T6. The light emitting layer EML may include a hole transport layer, an organic material layer (or a light generating layer), and/or an electron transport layer.

The light receiving element LRD and the bank BNK may be disposed in the sensor layer SSL. The light receiving element LRD may be an optical fingerprint sensor. In an embodiment, as shown in FIG. 6, the light receiving element LRD may recognize a fingerprint by sensing light reflected by a ridge FR and a valley FV between the ridges FR of a finger F. In an embodiment, for example, when a user's finger F touches the window WD, first light L1 emitted from the light emitting element LED (or the light emitting layer EML) may be reflected by the ridge FR or the valley FV of the finger F, and reflected second light L2 may reach the light receiving element LRD (or a light receiving layer OPL) of the sensor layer SSL. The light receiving element LRD may recognize a pattern of the user's fingerprint by distinguishing between the second light L2 reflected from the ridge FR of the finger F and the second light L2 reflected from the valley FV of the finger F. The light receiving element LRD may be electrically connected to the ninth transistor T9. The light receiving element LRD may include the first electrode EL1 (or a first sensor electrode), the light receiving layer OPL (or a photoelectric conversion layer), and a second electrode EL2 (or a second sensor electrode).

The anode electrode AE and the first electrode EL1 may be disposed on the eighth insulating layer INS8. The anode electrode AE and the first electrode EL1 may include or be formed of a metal layer such as silver (Ag), magnesium (Mg), aluminum (AI), platinum (Pt), palladium (Pd), gold (Au), nickel (Ni), neodymium (Nd), iridium (Ir), chromium (Cr), and an alloy thereof, indium tin oxide (ITO), indium zinc oxide (IZO), zinc oxide (ZnO), and/or indium tin zinc oxide (ITZO). The anode electrode AE may be electrically connected to the first bridge pattern BRP1 through a contact hole defined or formed through the eighth insulating layer INS8. The first electrode EL1 may be electrically connected to the second bridge pattern BRP through a contact hole defined or formed through the eighth insulating layer INS8. The anode electrode AE and the first electrode EL1 may be formed simultaneously during a same process, but are not necessarily limited thereto.

The bank BNK may be disposed on the anode electrode AE, the first electrode EL1, and/or the eighth insulating layer INS8.

The bank BNK may be a pixel defining layer that partitions a light emitting area EMA of the sub-pixel PXL and a light receiving area FXA of the light sensing pixel PSR. The bank BNK may be provided with openings corresponding to the light emitting area EMA and the light receiving area FXA. The bank BNK may be an organic layer including an organic material (or substance). The organic material may include acryl resin, epoxy resin, phenolic resin, polyamide resin, and polyimide resin.

According to an embodiment, the bank BNK may include a light absorbing material or may be coated with a light absorbing material to serve to absorb light introduced from an outside. In an embodiment, for example, BNK may include a carbon-based black pigment. However, the disclosure is not limited thereto, and the bank BNK may include an opaque metal material such as chromium (Cr), molybdenum (Mo), an alloy of molybdenum (Mo) and titanium (Ti) (MoTi), tungsten (W), vanadium (V), niobium (Nb), tantalum (Ta), manganese (Mn), cobalt (Co), or nickel (Ni) having high light absorption rate.

The light emitting layer EML may be disposed on the anode electrode AE. The light emitting layer EML may include an organic light emitting layer. According to an organic material included in the light emitting layer EML, the light emitting layer EML may emit red light, green light, or blue light, but is not limited thereto.

The light receiving layer OPL may be disposed on the first electrode EL1. The light receiving layer OPL may sense an intensity of light by emitting an electron correspondingly to light of a specific wavelength band.

The light receiving layer OPL may include a low molecular organic material (or substance). In an embodiment, for example, the light receiving layer OPL may include or be formed of a phthalocyanine compound including one or more metals selected from copper (Cu), iron (Fe), nickel (Ni), cobalt (Co), manganese (Mn), aluminum (AI), palladium (Pd), tin (Sn), indium (In), lead (Pb), titanium (Ti), rubidium (Rb), vanadium (V), gallium (Ga), terbium (Tb), cerium (Ce), lanthanum (La), and zinc (Zn).

According to an embodiment, the light receiving layer OPL may be configured as two layers including a layer including a phthalocyanine compound including one or more metals selected from copper (Cu), iron (Fe), nickel (Ni), cobalt (Co), manganese (Mn), aluminum (AI), palladium (Pd), tin (Sn), indium (In), lead (Pb), titanium (Ti), rubidium (Rb), vanadium (V), gallium (Ga), terbium (Tb), cerium (Ce), lanthanum (La), and zinc (Zn), and a layer including C60, or may be configured as a single mixed layer in which a phthalocyanine compound and C60 are mixed.

In an embodiment, the light receiving layer OPL may determine a light detection band of the light sensor by controlling selection of a metal component included in the phthalocyanine compound. In an embodiment, for example, a phthalocyanine compound including copper may absorb a visible light wavelength of a band of about 600 nanometers (nm) to about 800 nm, and a phthalocyanine compound including tin (Sn) may absorb a near infrared wavelength of a band of about 800 nm to about 1000 nm. Therefore, by controlling selection of a metal included in the phthalocyanine compound, a light sensor capable of detecting a wavelength of a band desired by the user may be implemented. In an embodiment, for example, the light receiving element LRD may be formed to selectively absorb a wavelength of a red light band, a wavelength of a green light band, or a wavelength of a blue light band through the light receiving layer OPL.

The cathode electrode CE may be disposed on the light emitting layer EML, and the second electrode EL2 may be disposed on the light receiving layer OPL. The cathode electrode CE and the second electrode EL2 may be a common electrode formed integrally in the display area DA. The second power voltage VSS may be supplied to the cathode electrode CE and the second electrode EL2.

The cathode electrode CE and the second electrode EL2 may include or be formed of a metal layer such as Ag, Mg, Al, Pt, Pd, Au, Ni, Nd, Ir, and Cr, and/or a transparent conductive layer such as ITO, IZO, ZnO, and ITZO. In an embodiment, the cathode electrode CE and the second electrode EL2 may be formed as a multilayer of a double layer or more including a metal thin layer, and for example, may be formed as a triple layer of ITO/Ag/ITO.

A thin film encapsulation layer TFL may be entirely formed on the cathode electrode CE and the second electrode EL2.

The thin film encapsulation layer TFL may be formed as a single layer, but may also be formed as a multilayer. The thin film encapsulation layer TFL may include a plurality of insulating layers covering the light emitting element LED and the light receiving device LRD. In an embodiment, the thin film encapsulation layer TFL may include at least one inorganic layer and at least one organic layer. In an embodiment, for example, the thin film encapsulation layer TFL may have a structure in which an inorganic layer and an organic layer are alternately stacked.

A color filter layer CFL may be disposed on the thin film encapsulation layer TFL. The color filter layer CFL may include a light blocking pattern and a color filter. The light blocking pattern may be disposed in the non-emission area NEA surrounding the light emitting area EMA of the sub-pixel PXL and the light receiving area FXA of the light sensing pixel PSR, and the color filter may be disposed in the light emitting area EMA and the light receiving area FXA. The color filter layer CFL may also be utilized as an anti-reflection layer blocking external light reflection. The window WD may be disposed on the color filter layer CFL.

FIG. 7 is a plan view schematically illustrating the data line, the readout line, the bridge line, the connection line, the first line, and the second line of the display device of FIG. 1.

Referring to FIG. 7, an embodiment of the display device DD (or the display panel DP) may include the substrate SUB, the line unit (refer to ‘LP’ of FIG. 1), and/or the pad unit PDP.

The pad unit PDP may be positioned in the pad area PDA and may include the first pad unit PDP1 and the second pad unit PDP2 electrically connected to the line unit LP. The first pad unit PDP1 may include a first pad P1 electrically connected to the first line (refer to ‘LP1’ of FIG. 1), and the second pad unit PDP2 may include a second pad P2 electrically connected to the second line (refer to ‘LP2’ of FIG. 1). The first pad unit PDP1 and the second pad unit PDP2 may be disposed to be spaced apart from each other physically and electrically in the pad area PDA. In an embodiment, for example, the second pad unit PDP2 may be positioned at a center portion of the pad area PDA, and the first pad unit PDP1 may be positioned at an edge portion of the substrate SUB in the pad area PDA. The first pad unit PDP1 may be positioned at each of both opposing sides of the second pad unit PDP2, but is not necessarily limited thereto.

The line unit LP may be positioned in the fan-out area FTA, and may include the first line LP1 electrically connected to the first pad unit PDP1 and the second line LP2 electrically connected to the second pad unit PDP2. The first line LP1 and the second line LP2 may be disposed to be spaced apart from each other physically and electrically in the fan-out area FTA. In an embodiment, for example, the second line LP2 may be positioned at a center portion of the fan-out area FTA, and the first line LP1 may be positioned at an edge portion of the substrate SUB in the fan-out area FTA. The first line LP1 may be positioned at each of both opposing sides of the second line LP2, but is not necessarily limited thereto.

The first line LP1 may include first lines electrically connected to readout lines RX1 to RX4 and RXk+3 to RXk+5 positioned in the first area DA1 through a first contact portion CNT1. The first lines may include a 1a-th line LP1a, a 1c-th line LP1c, a 1g-th line LP1g, a 1h-th line LP1h, a 1j-th line LP1j, and a 1l-th line LP1l.

In an embodiment, the first line LP1 may include other first lines electrically connected to the connection line CNL extending from the first area DA1 to the second area DA2 through the first contact portion CNT1. The other first lines may include a 1b-th line LP1b, a 1d-th line LP1d, a 1f-th line LP1f, a 1i-th line LP1i, a 1k-th line LP1k, and a 1m-th line LP1m.

The second line LP2 may include second lines electrically connected to data lines D4 to Dk+2 positioned in the second area DA2 through a second contact portion CNT2. The second lines may include a 2b-th line LP2b, a 2d-th line LP2d, a 2f-th line LP2f, a 2h-th line LP2h, a 2j-th line LP2j, and a 2l-th line PL2l.

In an embodiment, the second line LP2 may include other second lines electrically connected to the bridge line BRL extending from the second area DA2 to the first area DA1 through the second contact portion CNT2. The other second lines may include a 2a-th line LP2a, a 2c-th line LP2c, a 2e-th line LP2e, a 2g-th line LP2g, a 2i-th line LP2i, a 2k-th line LP2k, a 2l-th line LP2l, and a 2m-th line LP2m.

Hereinafter, when at least one of the 1a-th to 1m-th lines LP1a to LP1m is arbitrarily referred to or when the 1a-th to 1m-th lines LP1a to LP1m are collectively referred to, the at least one of the 1a-th to 1m-th lines LP1a to LP1m or the 1a-th to 1m-th lines LP1a to LP1m is or are referred to as “first line LP1” or “first lines LP1”. In addition, when at least one of the 2a-th to 2m-th lines LP2a to LP2m is arbitrarily referred to or the 2a-th to 2m-th lines LP2a to LP2m are collectively referred to, the at least one of the 2a-th to 2m-th lines LP2a to LP2m or the 2a-th to 2m-th lines LP2a to LP2m is or are referred to as, “second line LP2” or “second lines LP2”.

The substrate SUB may include the display area DA and the non-display area NDA. The display area DA may include the first area DA1 and the second area DA2.

Signal lines to which various signals are applied may be disposed in the first area DA1 and the second area DA2. In an embodiment, for example, data lines D1 to Dk+6 to which a data signal is applied may be disposed in the first area DA1 and the second area DA2. The data lines D1 to Dk+6 may extend along a second direction DR2 in the first area DA1 and the second area DA2.

The readout lines RX1 to RXk+5 for receiving a sensing signal from the light sensing pixel PSR may be disposed in the first area DA1 and the second area DA2. The readout lines RX1 to RXk+5 may extend along the second direction DR2 in the first area DA1 and the second area DA2.

In addition to the data lines D1 to Dk+6 and the readout lines RX1 to RXk+5, various signal lines of a power line, a scan line, and the like may be disposed in the first area DA1 and the second area DA2.

In the first area DA1 and the second area DA2, the sub-pixel PXL may be disposed or positioned in an area (for example, a pixel area) defined or partitioned by scan lines (for example, refer to ‘S1i to S4i’ of FIG. 4) and data lines (for example, D1 to Dk+6).

In the first area DA1 and the second area DA2, the light sensing pixel PSR may be disposed or positioned in an area defined or partitioned by scan lines (for example, S1i to S4i) and readout lines (for example, RX1 to RXk+5).

In the first area DA1, the first data line D1, the second data line D2, the third data line D3, the (k+3)-th data line Dk+3, the (k+4)-th data line Dk+4, the (k+5)-th data line Dk+5, and/or the (k+6)-th data line Dk+6 may be disposed.

In the second area DA2, the fourth data line D4, the fifth data line D5, the sixth data line D6, the k-th data line Dk, the (k+1)-th data line Dk+1, and/or the (k+2)-th data line Dk+2 may be disposed.

In the first area DA1, the first readout line RX1, the second readout line RX2, the third readout line RX3, the fourth readout line RX4, the (k+3)-th readout line RXk+3, the (k+4)-th readout line RXk+4, and/or the (k+5)-th readout line RXk+5 may be disposed.

In the second area DA2, the fifth readout line RX5, the sixth readout line RX6, the seventh readout line RX7, the k-th readout line RXk, the (k+1)-th readout line RXk+1, and/or the (k+2)-th readout line RXk+2 may be disposed.

The connection line CNL and the bridge line BRL may be disposed in the display area DA. The connection line CNL and the bridge line BRL may be spaced apart from each other in the display area DA. The connection line CNL and the bridge line BRL may be disposed in the display area DA not to overlap each other.

In an embodiment, the connection line CNL may extend from the first area DA1 to the second area DA2. In an embodiment, for example, the connection line CNL may be routed from an edge portion (or an outer portion) of the display area DA to a center portion or (an inner portion) of the display area DA. The connection line CNL may be electrically connected to the corresponding first line LP1 through the first contact portion CNT1. The connection line CNL may include a horizontal connection line extending in a first direction DR1 and crossing from the first area DA1 to the second area DA2, and a vertical connection line disposed in the first area DA1 and extending in the second direction DR2.

The connection line CNL may include first to sixth connection lines CNL1, CNL2, CNL3, CNL4, CNL5, and CNL6. Each of the first to sixth connection lines CNL1, CNL2, CNL3, CNL4, CNL5, and CNL6 may include a vertical connection line positioned in the first area DA1 and extending in the second direction DR2, and a horizontal connection line extending in the first direction and positioned to cross from the first area DA1 and the second area DA2.

The vertical connection line of the first connection line CNL1 may be electrically connected to the 1b-th line LP1b through the first contact portion CNT1, and may be electrically connected to the horizontal connection line of the first connection line CNL1 through a third contact hole CH3. The horizontal connection line of the first connection line CNL1 may be electrically connected to the seventh readout line RX7 disposed in the second area DA2 through a fourth contact hole CH4. The first connection line CNL1 may electrically connect the seventh readout line RX7 and the 1b-th line LP1b. Accordingly, a sensing signal from the light sensing pixel PSR of the second area DA2 received from the seventh readout line RX7 may be transmitted to the driver DIC through the 1b-th line LP1b through the first connection line CNL1.

The vertical connection line of the second connection line CNL2 may be electrically connected to the 1d-th line LP1d through the first contact portion CNT1, and may be electrically connected to the horizontal connection line of the second connection line CNL2 through the third contact hole CH3. The horizontal connection line of the second connection line CNL2 may be electrically connected to the sixth readout line RX6 disposed in the second area DA2 through the fourth contact hole CH4. The second connection line CNL2 may electrically connect the sixth readout line RX6 and the 1d-th line LP1d. Accordingly, a sensing signal from the light sensing pixel PSR of the second area DA2 received from the sixth readout line RX6 may be transmitted to the driver DIC through the 1d-th line LP1d through the second connection line CNL2.

The vertical connection line of the third connection line CNL3 may be electrically connected to the 1f-th line LP1f through the first contact portion CNT1, and may be electrically connected to the horizontal connection line of the third connection line CNL3 through the third contact hole CH3. The horizontal connection line of the third connection line CNL3 may be electrically connected to the fifth readout line RX5 disposed in the second area DA2 through the fourth contact hole CH4. The third connection line CNL3 may electrically connect the fifth readout line RX5 and the 1f-th line LP1f. Accordingly, a sensing signal from the light sensing pixel PSR of the second area DA2 received from the fifth readout line RX5 may be transmitted to the driver DIC through the 1f-th line LP1d through the third connection line CNL3.

The vertical connection line of the fourth connection line CNL4 may be electrically connected to the 1m-th line LP1m through the first contact portion CNT1, and may be electrically connected to the horizontal connection line of the fourth connection line CNL4 through the third contact hole CH3. The horizontal connection line of the fourth connection line CNL4 may be electrically connected to the k-th readout line RXk disposed in the second area DA2 through the fourth contact hole CH4. The fourth connection line CNL4 may electrically connect the k-th readout line RXk and the 1m-th line LP1m. Accordingly, a sensing signal from the light sensing pixel PSR of the second area DA2 received from the k-th readout line RXk may be transmitted to the driver DIC through the 1m-th line LP1m through the fourth connection line CNL4.

The vertical connection line of the fifth connection line CNL5 may be electrically connected to the 1k-th line LP1k through the first contact portion CNT1, and may be electrically connected to the horizontal connection line of the fifth connection line CNL5 through the third contact hole CH3. The horizontal connection line of the fifth connection line CNL5 may be electrically connected to the (k+1)-th readout line RXk+1 disposed in the second area DA2 through the fourth contact hole CH4. The fifth connection line CNL5 may electrically connect the (k+1)-th readout line RXk+1 and the 1k-th line LP1k. Accordingly, a sensing signal from the light sensing pixel PSR of the second area DA2 received from the (k+1)-th readout line RXk+1 may be transmitted to the driver DIC through the 1k-th line LP1k through the fifth connection line CNL5.

The vertical connection line of the sixth connection line CNL6 may be electrically connected to the 1i-th line LP1i through the first contact portion CNT1, and may be electrically connected to the horizontal connection line of the sixth connection line CNL6 through the third contact hole CH3. The horizontal connection line of the sixth connection line CNL6 may be electrically connected to the (k+2)-th readout line RXk+2 disposed in the second area DA2 through the fourth contact hole CH4. The sixth connection line CNL6 may electrically connect the (k+2)-th readout line RXk+2 and the 1i-th line LP1i. Accordingly, a sensing signal from the light sensing pixel PSR of the second area DA2 received from the (k+2)-th readout line RXk+2 may be transmitted to the driver DIC through the 1i-th line LP1i through the sixth connection line CNL6.

One end of the vertical connection line may be electrically connected to the corresponding first line LP1 through the first contact portion CNT1, and another end of the vertical connection line may be electrically connected to the corresponding horizontal connection line through the third contact hole CH3. One end of the horizontal connection line may be electrically connected to the vertical connection line through the third contact hole CH3, and another end of the horizontal connection line may be electrically connected to the corresponding readout line positioned in the second area DA2 through the fourth contact hole CH4.

In an embodiment, the bridge line BRL may extend from the second area DA2 to the first area DA1. In an embodiment, for example, the bridge line BRL may be routed from a center (or an inside) of the display area DA to an edge (or an outside) of the display area DA. The bridge line BRL may be electrically connected to the corresponding second line LP2 through the second contact portion CNT2. The bridge line BRL may include a vertical bridge line disposed in the second area DA2 and extending in the second direction DR2, and a horizontal bridge line electrically connected to the vertical bridge line, extending in the first direction DR1 crossing the second direction DR2, and crossing the first area DA1 from the second area DA2.

The bridge line BRL may include first to seventh bridge lines BRL1, BRL2, BRL3, BRL4, BRL5, BRL6, and BRL7. Each of the first to seventh bridge lines BRL1, BRL2, BRL3, BRL4, BRL5, BRL6, BRL7 may include a vertical bridge line positioned in the second area DA2 and extending in the second direction DR2, and a horizontal bridge line extending in the first direction DR1 and positioned across the first area DA1 from the second area DA2.

The vertical bridge line of the first bridge line BRL1 may be electrically connected to the 2e-th line LP2e through the second contact portion CNT2, and may be electrically connected to the horizontal bridge line of the first bridge line BRL1 through the first contact hole CH1. The horizontal bridge line of the first bridge line BRL1 may be electrically connected to the first data line D1 disposed in the first area DA1 through the second contact hole CH2. The first bridge line BRL1 may electrically connect the first data line D1 and the 2e-th line LP2e. Accordingly, a data signal transmitted from the driver DIC to the 2e-th line LP2e may be transmitted to the first data line D1 through the first bridge line BRL1.

The vertical bridge line of the second bridge line BRL2 may be electrically connected to the 2c-th line LP2c through the second contact portion CNT2, and may be electrically connected to the horizontal bridge line of the second bridge line BRL2 through the first contact hole CH1. The horizontal bridge line of the second bridge line BRL2 may be electrically connected to the second data line D2 disposed in the first area DA1 through the second contact hole CH2. The second bridge line BRL2 may electrically connect the second data line D2 and the 2c-th line LP2c. Accordingly, a data signal transmitted from the driver DIC to the 2c-th line LP2c may be transmitted to the second data line D2 through the second bridge line BRL2.

The vertical bridge line of the third bridge line BRL3 may be electrically connected to the 2a-th line LP2a through the second contact portion CNT2, and may be electrically connected to the horizontal bridge line of the third bridge line BRL3 through the first contact hole CH1. The horizontal bridge line of the third bridge line BRL3 may be electrically connected to the third data line D3 disposed in the first area DA1 through the second contact hole CH2. The third bridge line BRL3 may electrically connect the third data line D3 and the 2a-th line LP2a. Accordingly, a data signal transmitted from the driver DIC to the 2a-th line LP2a may be transmitted to the third data line D3 through the third bridge line BRL3.

The vertical bridge line of the fourth bridge line BRL4 may be electrically connected to the 2g-th line LP2g through the second contact portion CNT2, and may be electrically connected to the horizontal bridge line of the fourth bridge line BRL4 through the first contact hole CH1. The horizontal bridge line of the fourth bridge line BRL4 may be electrically connected to the (k+6)-th data line Dk+6 disposed in the first area DA1 through the second contact hole CH2. The fourth bridge line BRL4 may electrically connect the (k+6)-th data line Dk+6 and the 2g-th line LP2g. Accordingly, a data signal transmitted from the driver DIC to the 2g-th line LP2g may be transmitted to the (k+6)-th data line Dk+6 through the fourth bridge line BRL4.

The vertical bridge line of the fifth bridge line BRL5 may be electrically connected to the 2i-th line LP2i through the second contact portion CNT2, and may be electrically connected to the horizontal bridge line of the fifth bridge line BRL5 through the first contact hole CH1. The horizontal bridge line of the fifth bridge line BRL5 may be electrically connected to the (k+5)-th data line Dk+5 disposed in the first area DA1 through the second contact hole CH2. The fifth bridge line BRL5 may electrically connect the (k+5)-th data line Dk+5 and the 2i-th line LP2i. Accordingly, a data signal transmitted from the driver DIC to the 2i-th line LP2i may be transmitted to the (k+5)-th data line Dk+5 through the fifth bridge line BRL5.

The vertical bridge line of the sixth bridge line BRL6 may be electrically connected to the 2k-th line LP2k through the second contact portion CNT2, and may be electrically connected to the horizontal bridge line of the sixth bridge line BRL6 through the first contact hole CH1. The horizontal bridge line of the sixth bridge line BRL6 may be electrically connected to the (k+4)-th data line Dk+4 disposed in the first area DA1 through the second contact hole CH2. The sixth bridge line BRL6 may electrically connect the (k+4)-th data line Dk+4 and the 2k-th line LP2k. Accordingly, a data signal transmitted from the driver DIC to the 2k-th line LP2k may be transmitted to the (k+4)-th data line Dk+4 through the sixth bridge line BRL6.

The vertical bridge line of the seventh bridge line BRL7 may be electrically connected to the 2m-th line LP2m through the second contact portion CNT2, and may be electrically connected to the horizontal bridge line of the seventh bridge line BRL7 through the first contact hole CH1. The horizontal bridge line of the seventh bridge line BRL7 may be electrically connected to the (k+3)-th data line Dk+3 disposed in the first area DA1 through the second contact hole CH2. The seventh bridge line BRL7 may electrically connect the (k+3)-th data line Dk+3 and the 2m-th line LP2m. Accordingly, a data signal transmitted from the driver DIC to the 2m-th line LP2m may be transmitted to the (k+3)-th data line Dk+3 through the seventh bridge line BRL7.

According to an embodiment, as described above, the first pad unit PDP1 (or the first pad P1) electrically connected to the readout line and the second pad unit PDP2 (or the second pad P2) electrically connected to the data line may be disposed to be spaced apart from each other in the pad area PDA, and each may be intensively disposed in a specific area of the pad area PDA. In an embodiment, for example, the second pad unit PDP2 may be positioned at a center of the pad area PDA to correspond to the second area DA2 of the display area DA, and the first pad unit PDP1 may be positioned at both edges of the pad area PDA to correspond to the first area DA1 of the display area DA. In such an embodiment, a phenomenon in which the sensing signal of the light sensing pixel PSR transmitted to the driver DIC through the first pad unit PDP1 is affected by the data signal transmitted to the data line through the second pad unit PDP2 may be substantially reduced or effectively prevented. In addition, a phenomenon in which the data signal transmitted to the data line through the second pad unit PDP2 is affected by the sensing signal of the light sensing pixel PSR transmitted to the driver DIC through the first pad unit PDP1 may be substantially reduced or effectively prevented. In general, when a readout pad electrically connected to the readout line and a data pad electrically connected to the data line are alternately disposed in the pad area PDA, a coupling cap (or a parasitic capacitance) may be generated between the readout pad and the data pad. As described above, in an embodiment, since the first pad unit PDP1 and the second pad unit PDP2 may be disposed to be separated, and each of the first pad unit PDP1 and the second pad unit PDP2 may be positioned only in a specific area in the pad area PDA, the coupling cap between the first pad unit PDP1 and the second pad unit PDP2 may be effectively prevented, and thus reliability of the display device DD may be improved.

According to an embodiment, the first line LP1 electrically connected to the readout line and the second line LP2 electrically connected to the data line may be disposed to be spaced apart from each other in the fan-out area FTA, and each may be intensively disposed in a specific area of the fan-out area FTA. In an embodiment, for example, the second line LP2 may be positioned at a center of the fan-out area FTA to correspond to the second area DA2 of the display area DA, and the first line LP1 may be positioned at both opposing edge portions of the fan-out area FTA to correspond to the first area DA1. In such an embodiment, a phenomenon in which the sensing signal of the light sensing pixel PSR transmitted to the first pad unit PDP1 through the first line LP1 is affected by the data signal transmitted to the data line through the second line LP2 may be substantially reduced or effectively prevented. In addition, a phenomenon in which the data signal transmitted to the data line through the second line LP2 is affected by the sensing signal of the light sensing pixel PSR transmitted to the first pad unit PDP1 through the first line LP1 may be substantially reduced or effectively prevented. In general, when a readout fan-out line electrically connected to the readout line and a data fan-out line electrically connected to the data line are alternately disposed in the fan-out area FTA, a coupling cap (or a parasitic capacitance) may be generated between the readout fan-out line and the data fan-out line. As described above, in an embodiment, since the first line LP1 and the second line LP2 may be disposed to be separated and each may be positioned only in a specific area in the fan-out area FTA, the coupling cap between the first line LP1 and the second line LP2 may be effectively prevented, and thus reliability of the display device DD may be improved.

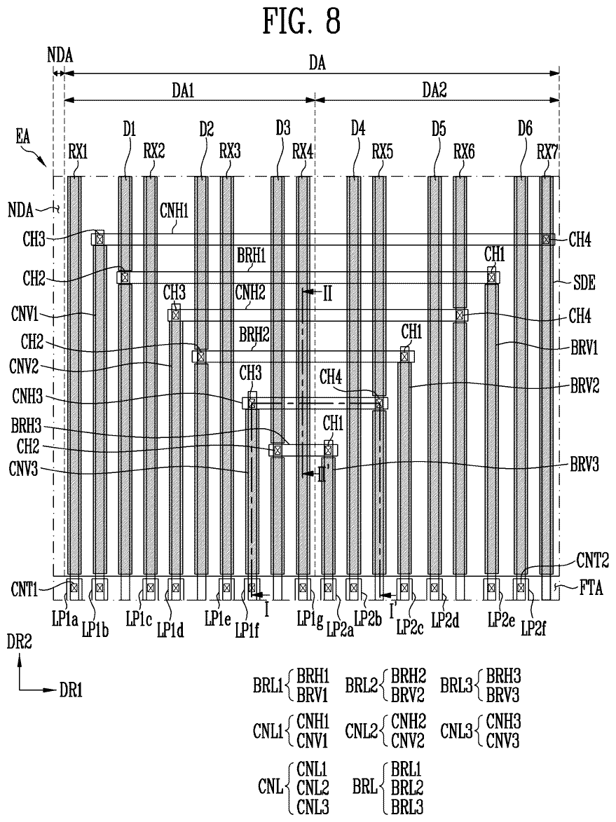

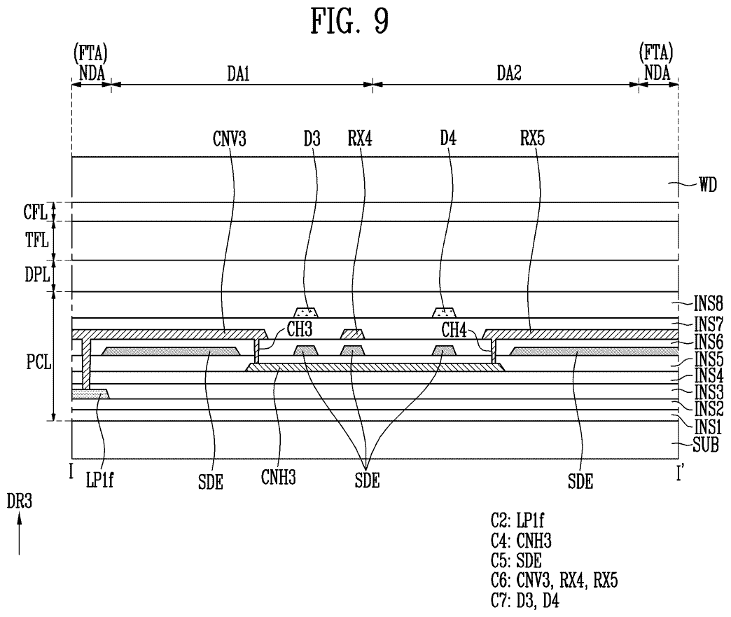

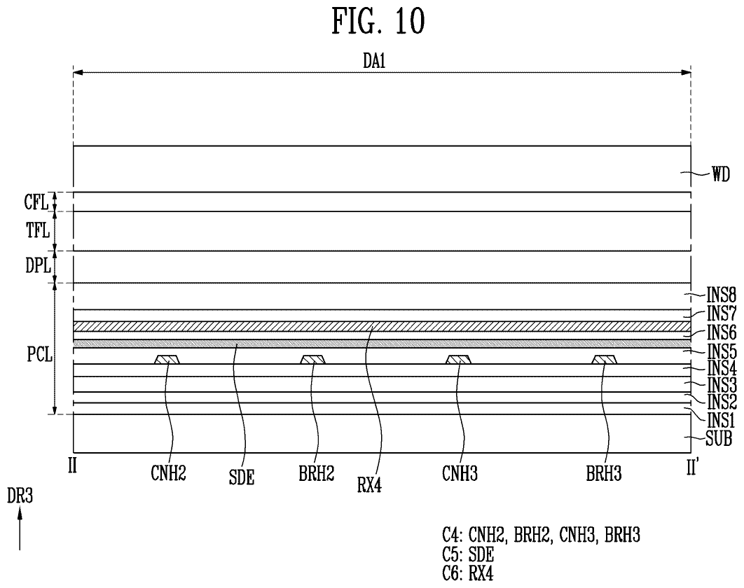

FIG. 8 is an enlarged plan view schematically illustrating an area EA of FIG. 7. FIGS. 9, 11, 13, 15, 17, 19, 21, 23, 25, 27, 29, and 31 are cross-sectional views taken along line I-I′ of FIG. 8, illustrating a display device according to various embodiments. FIGS. 10, 12, 14, 16, 18, 20, 22, 24, 26, 28, 30, and 32 are cross-sectional views taken along line II-II′ of FIG. 8, illustrating a display device according to various embodiments.

Referring to FIGS. 8 to 10, the first to third connection lines CNL1, CNL2, and CNL3 may extend from the first area DA1 to the second area DA2. The first to third bridge lines BRL1, BRL2, and BRL3 may extend from the second area DA2 to the first area DA1.

The first to third connection lines CNL1, CNL2, and CNL3 may have a partially bent shape to be electrically connected to the readout lines disposed in the second area DA2. The first to third bridge lines BRL1, BRL2, and BRL3 may have a partially bent shape to be electrically connected to the data lines disposed in the first area DA1.

In an embodiment, the first to third connection lines CNL1, CNL2, and CNL3 may be spaced apart from the first to third bridge lines BRL1, BRL2, and BRL3. The first to third connection lines CNL1, CNL2, and CNL3 may not overlap the first to third bridge lines BRL1, BRL2, and BRL3.

The first connection line CNL1 may include a first vertical connection line CNV1 extending in the second direction DR2 in the first area DA1 and a first horizontal connection line CNH1 extending in the first direction DR1 from the first area DA1 to the second area DA2. One end of the first horizontal connection line CNH1 may be positioned in the first area DA1, and another end of the first horizontal connection line CNH1 may be positioned in the second area DA2.

One end of the first vertical connection line CNV1 may be electrically connected to the 1b-th line LP1b through the first contact portion CNT1. Another end of the first vertical connection line CNV1 may be electrically connected to the first horizontal connection line CNH1 through the third contact hole CH3.

One end of the first horizontal connection line CNH1 may be electrically connected to the first vertical connection line CNV1 through the third contact hole CH3. Another end of the first horizontal connection line CNH1 may be electrically connected to the seventh readout line RX7 disposed in the second area DA2 through the fourth contact hole CH4.

The second connection line CNL2 may include a second vertical connection line CNV2 extending in the second direction DR2 in the first area DA1 and a second horizontal connection line CNH2 extending in the first direction DR1 from the first area DA1 to the second area DA2. One end of the second horizontal connection line CNH2 may be positioned in the first area DA1, and another end of the second horizontal connection line CNH2 may be positioned in the second area DA2.

One end of the second vertical connection line CNV2 may be electrically connected to the 1d-th line LP1d through the first contact portion CNT1. Another end of the second vertical connection line CNV2 may be electrically connected to the second horizontal connection line CNH2 through the third contact hole CH3.

One end of the second horizontal connection line CNH2 may be electrically connected to the second vertical connection line CNV2 through the third contact hole CH3. Another end of the second horizontal connection line CNH2 may be electrically connected to the sixth readout line RX6 disposed in the second area DA2 through the fourth contact hole CH4.

The third connection line CNL3 may include a third vertical connection line CNV3 extending in the second direction DR2 in the first area DA1 and a third horizontal connection line CNH3 extending in the first direction DR1 from the first area DA1 to the second area DA2. One end of the third horizontal connection line CNH3 may be positioned in the first area DA1, and another end of the third horizontal connection line CNH3 may be positioned in the second area DA2.

One end of the third vertical connection line CNV3 may be electrically connected to the 1f-th line LP1f through the first contact portion CNT1. Another end of the third vertical connection line CNV3 may be electrically connected to the third horizontal connection line CNH3 through the third contact hole CH3.

One end of the third horizontal connection line CNH3 may be electrically connected to the third vertical connection line CNV3 through the third contact hole CH3. Another end of the third horizontal connection line CNH3 may be electrically connected to the fifth readout line RX5 disposed in the second area DA2 through the fourth contact hole CH4.

The first bridge line BRL1 may include a first vertical bridge line BRV1 extending in the second direction DR2 in the second area DA2 and a first horizontal bridge line BRH1 extending in the first direction DR1 from the second area DA2 to the first area DA1. One end of the first horizontal bridge line BRH1 may be positioned in the second area DA2, and another end of the first horizontal bridge line BRH1 may be positioned in the first area DA1.

One end of the first vertical bridge line BRV1 may be electrically connected to the 2e-th line LP2e through the second contact portion CNT2. Another end of the first vertical bridge line BRV1 may be electrically connected to the first horizontal bridge line BRH1 through the first contact hole CH1.

One end of the first horizontal bridge line BRH1 may be electrically connected to the first vertical bridge line BRV1 through the first contact hole CH1. Another end of the first horizontal bridge line BRH1 may be electrically connected to the first data line D1 positioned in the first area DA1 through the second contact hole CH2.

The second bridge line BRL2 may include a second vertical bridge line BRV2 extending in the second direction DR2 in the second area DA2 and a second horizontal bridge line BRH2 extending in the first direction DR1 from the second area DA2 to the first area DA1. One end of the second horizontal bridge line BRH2 may be positioned in the second area DA2, and another end of the second horizontal bridge line BRH2 may be positioned in the first area DA1.

One end of the second vertical bridge line BRV2 may be electrically connected to the 2c-th line LP2c through the second contact portion CNT2. Another end of the second vertical bridge line BRV2 may be electrically connected to the second horizontal bridge line BRH2 through the first contact hole CH1.

One end of the second horizontal bridge line BRH2 may be electrically connected to the second vertical bridge line BRV2 through the first contact hole CH1. Another end of the second horizontal bridge line BRH2 may be electrically connected to the second data line D2 positioned in the first area DA1 through the second contact hole CH2.

The third bridge line BRL3 may include a third vertical bridge line BRV3 extending in the second direction DR2 in the second area DA2 and a third horizontal bridge line BRH3 extending in the first direction DR1 from the second area DA2 to the first area DA1. One end of the third horizontal bridge line BRH3 may be positioned in the second area DA2, and another end of the third horizontal bridge line BRH3 may be positioned in the first area DA1.

One end of the third vertical bridge line BRV3 may be electrically connected to the 2a-th line LP2a through the second contact portion CNT2. Another end of the third vertical bridge line BRV3 may be electrically connected to the third horizontal bridge line BRH3 through the first contact hole CH1.

One end of the third horizontal bridge line BRH3 may be electrically connected to the third vertical bridge line BRV3 through the first contact hole CH1. Another end of the third horizontal bridge line BRH3 may be electrically connected to the third data line D3 positioned in the first area DA1 through the second contact hole CH2.

In an embodiment, each of the readout lines positioned in the first area DA1 may be directly connected to the corresponding first line LP1. In an embodiment, for example, the first readout line RX1 positioned in the first area DA1 may be electrically connected to the 1a-th line LP1a through the first contact portion CNT1. The second readout line RX2 positioned in the first area DA1 may be electrically connected to the 1c-th line LP1c through the first contact portion CNT1. The third readout line RX3 positioned in the first area DA1 may be electrically connected to the 1e-th line LP1e through the first contact portion CNT1. The fourth readout line RX4 positioned in the first area DA1 may be electrically connected to the 1g-th line LP1g through the first contact portion CNT1.

Each of the data lines positioned in the second area DA2 may be directly connected to the corresponding second line LP2. In an embodiment, for example, the fourth data line D4 positioned in the second area DA2 may be electrically connected to the 2b-th line LP2b through the second contact portion CNT2. The fifth data line D5 positioned in the second area DA2 may be electrically connected to the 2d-th line LP2d through the second contact portion CNT2. The sixth data line D6 positioned in the second area DA2 may be electrically connected to the 2f-th line LP2f through the second contact portion CNT2.

In an embodiment, shielding electrodes SDE may be further disposed in the first area DA1 and the second area DA2. The shielding electrodes SDE may be disposed between the readout lines (or the data lines) and the horizontal connection lines (or the horizontal bridge lines) to serve to minimize a coupling cap that may occur due to overlapping lines. The shielding electrodes SDE may extend in the second direction DR2 in the first area DA1 and the second area DA2. The shielding electrodes SDE may at least partially overlap the readout lines RX1, RX2, RX3, RX4, RX5, RX6, and RX7, respectively, in the third direction DR3. The shielding electrodes SDE may at least partially overlap the data lines D1, D2, D3, D4, D5, and D6, respectively. The shielding electrodes SDE may at least partially overlap the vertical connection lines CNV1, CNV2, and CNV3, respectively, in the third direction DR3. The shielding electrodes SDE may at least partially overlap the vertical bridge lines BRV1, BRV2, and BRV3, respectively, in the third direction DR3.

The above-described readout lines RX1, RX2, RX3, RX4, RX5, RX6, and RX7 may be formed of (or defined by) the sixth conductive layer C6. The readout lines RX1, RX2, RX3, RX4, RX5, RX6, and RX7 may be electrically connected to one end of the horizontal connection lines CNH1, CNH2, and CNH3 through the fourth contact hole CH4 defined or formed through the fifth and sixth insulating layers INS5 and INS6, respectively.

The vertical connection lines CNV1, CNV2, and CNV3 may be formed of (or defined by portions of) the sixth conductive layer C6. One end of the vertical connection lines CNV1, CNV2, and CNV3 may be electrically connected to the first lines LP1 through the first contact portion CNT1 defined or formed through the third to sixth insulating layers INS3, INS4, INS5, and INS6, respectively. The first lines LP1 may be formed of (or defined by portions of) the second conductive layer C2, but are not limited thereto. Another end of the vertical connection lines CNV1, CNV2, and CNV3 may be electrically connected to another end of the horizontal connection lines CNH1, CNH2, and CNH3 through the third contact hole CH3 defined or formed through the fifth and sixth insulating layers INS5 and INS6.

The horizontal connection lines CNH1, CNH2, and CNH3 may be formed of (or defined by portions of) the fourth conductive layer C4.

The data lines D1, D2, D3, D4, D5, and D6 may be formed of (or defined by portions of) the seventh conductive layer C7. The data lines D1, D2, D3, D4, D5, and D6 may be electrically connected to one end of the horizontal bridge lines BRH1, BRH2, and BRH3 through the second contact hole CH2 defined or formed through the fifth to seventh insulating layers INS5, INS6, and INS7, respectively.

The vertical bridge lines BRV1, BRV2, and BRV3 may be disposed in a same layer as the vertical connection lines CNV1, CNV2, and CNV3. In an embodiment, for example, the vertical bridge lines BRV1, BRV2, and BRV3 may be formed of (or defined by portions of) the sixth conductive layer C6. One end of the vertical bridge lines BRV1, BRV2, and BRV3 may be electrically connected to the second lines LP2 through the second contact portion CNT2 defined or formed through the third to sixth insulating layers INS3, INS4, INS5, and INS6, respectively. The second lines LP2 may be disposed in a same layer as the first lines LP1. The second lines LP2 may be formed of (or defined by portions of) the second conductive layer C2, but are not necessarily limited thereto. Another end of the vertical bridge lines BRV1, BRV2, and BRV3 may be electrically connected to another end of the horizontal bridge lines BRH1, BRH2, BRH3 through the first contact hole CH1 defined or formed through the fifth and sixth insulating layers INS5 and INS6.

The horizontal bridge lines BRH1, BRH2, and BRH3 may be formed of (or defined by portions of) the fourth conductive layer C4.

The shielding electrodes SDE may be formed of (or defined by portions of) the fifth conductive layer C5. The shielding electrodes SDE may be disposed between the readout lines RX1, RX2, RX3, RX4, RX5, RX6, and RX7 (or the data lines D1, D2, D3, D4, D5, and D6) and the horizontal connection lines CNH1, CNH2, and CNH3 (or the horizontal bridge lines BRH1, BRH2, and BRH3). Accordingly, crosstalk may be improved by minimizing a coupling cap that may occur due to overlapping lines.

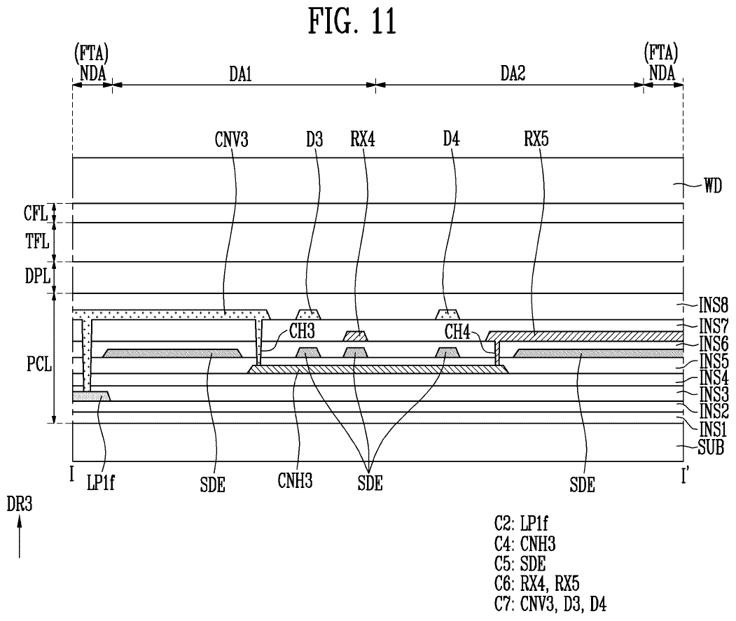

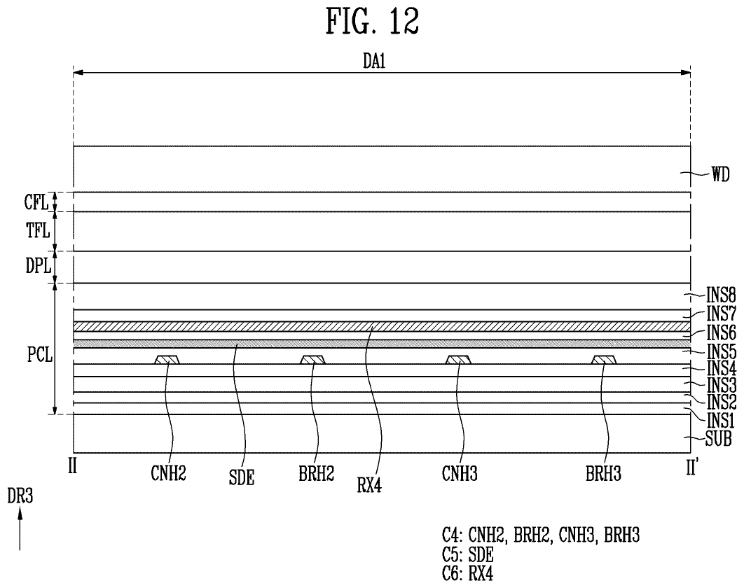

Referring to FIGS. 11 and 12, in another embodiment, the readout lines RX1, RX2, RX3, RX4, RX5, RX6, and RX7 may be formed of (or defined by portions of) the sixth conductive layer C6. The readout lines RX1, RX2, RX3, RX4, RX5, RX6, and RX7 may be electrically connected to one end of the horizontal connection lines CNH1, CNH2, and CNH3 through the fourth contact hole CH4 defined or formed through the fifth and sixth insulating layers INS5 and INS6, respectively.

The vertical connection lines CNV1, CNV2, and CNV3 may be formed of (or defined by portions of) the seventh conductive layer C7. One end of the vertical connection lines CNV1, CNV2, and CNV3 may be electrically connected to the first lines LP1 through the first contact portion CNT1 defined or formed through the third to seventh insulating layers INS3, INS4, INS5, INS6, and INS7, respectively. The first lines LP1 may be formed of (or defined by portions of) the second conductive layer C2, but are not necessarily limited thereto. Another end of the vertical connection lines CNV1, CNV2, and CNV3 may be electrically connected to another end of the horizontal connection lines CNH1, CNH2, and CNH3 through the third contact hole CH3 defined or formed through the fifth to seventh insulating layers INS5, INS6, and INS7.

The horizontal connection lines CNH1, CNH2, and CNH3 may be formed of (or defined by portions of) the fourth conductive layer C4.

The data lines D1, D2, D3, D4, D5, and D6 may be formed of (or defined by portions of) the seventh conductive layer C7. The data lines D1, D2, D3, D4, D5, and D6 may be electrically connected to one end of the horizontal bridge lines BRH1, BRH2, and BRH3 through the second contact hole CH2 defined or formed through the fifth to seventh insulating layers INS5, INS6, and INS7, respectively.

The vertical bridge lines BRV1, BRV2, and BRV3 may be disposed in the same layer as the vertical connection lines CNV1, CNV2, and CNV3. In an embodiment, for example, the vertical bridge lines BRV1, BRV2, and BRV3 may be formed of (or defined by portions of) the seventh conductive layer C7. One end of the vertical bridge lines BRV1, BRV2, and BRV3 may be electrically connected to the second lines LP2 through the second contact portion CNT2 defined or formed through the third to seventh insulating layers INS3, INS4, INS5, INS6, and INS7, respectively. The second lines LP2 may be disposed in the same layer as the first lines LP1. The second lines LP2 may be formed of (or defined by portions of) the second conductive layer C2, but are not necessarily limited thereto. Another end of the vertical bridge lines BRV1, BRV2, and BRV3 may be electrically connected to another end of the horizontal bridge lines BRH1, BRH2, and BRH3.

The horizontal bridge lines BRH1, BRH2, and BRH3 may be formed of (or defined by portions of) the fourth conductive layer C4.

The shielding electrodes SDE may be formed of (or defined by portions of) the fifth conductive layer C5. The shielding electrodes SDE may be disposed between the readout lines RX1, RX2, RX3, RX4, RX5, RX6, and RX7 (or the data lines D1, D2, D3, D4, D5, and D6) and the horizontal connection lines CNH1, CNH2, and CNH3 (or the horizontal bridge lines BRH1, BRH2, and BRH3). Accordingly, as described above, crosstalk may be improved by the shielding electrodes that minimize the coupling cap that may occur due to overlapping lines.

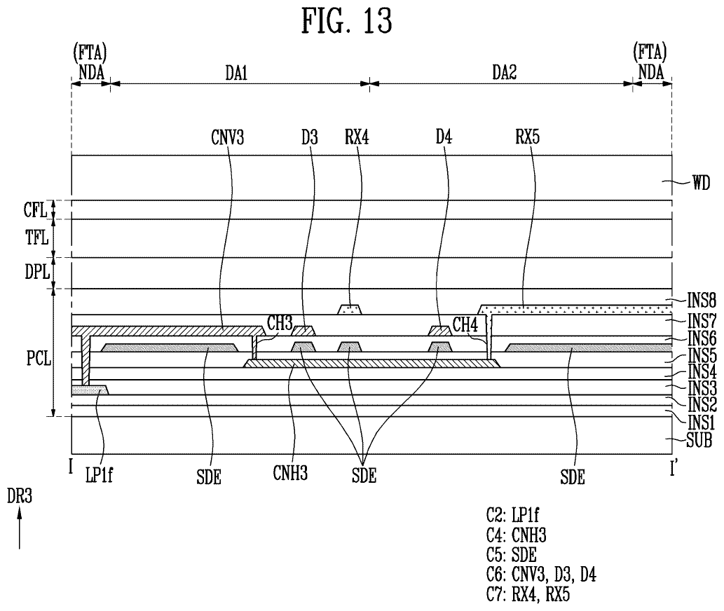

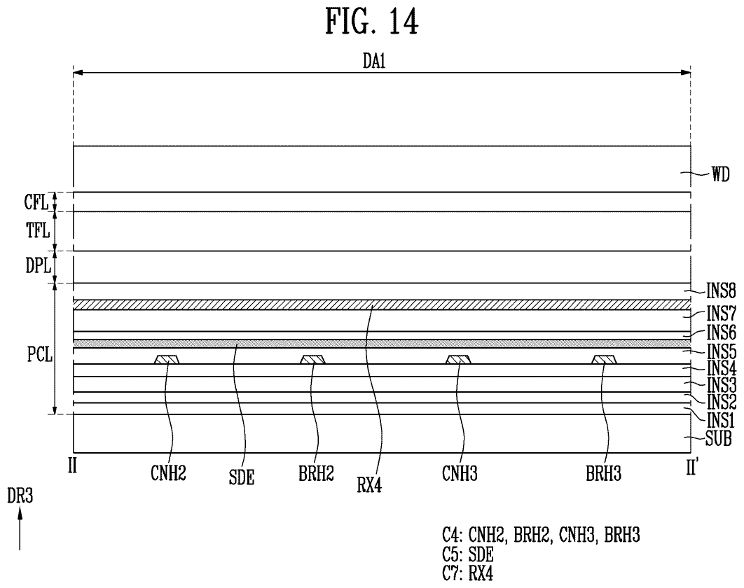

Referring to FIGS. 13 and 14, in another embodiment, the readout lines RX1, RX2, RX3, RX4, RX5, RX6, and RX7 may be formed of (or defined by portions of) the seventh conductive layer C7. The readout lines RX1, RX2, RX3, RX4, RX5, RX6, and RX7 may be electrically connected to one end of the horizontally connection lines CNH1, CNH2, and CNH3 through the fourth contact hole CH4 defined or formed through the fifth to seventh insulating layers INS5, INS6, and INS7, respectively.

The vertical connection lines CNV1, CNV2, and CNV3 may be formed of (or defined by portions of) the sixth conductive layer C6. One end of the vertical connection lines CNV1, CNV2, and CNV3 may be electrically connected to the first lines LP1 through the first contact portion CNT1 defined or formed through the third to sixth insulating layers INS3, INS4, INS5, and INS6, respectively. The first lines LP1 may be formed of (or defined by portions of) the second conductive layer C2, but are not necessarily limited thereto. Another end of the vertical connection lines CNV1, CNV2, and CNV3 may be electrically connected to another end of the horizontal connection lines CNH1, CNH2, and CNH3 through the third contact hole CH3 defined or formed through the fifth and sixth insulating layers INS5 and INS6.

The horizontal connection lines CNH1, CNH2, and CNH3 may be formed of (or defined by portions of) the fourth conductive layer C4.

The data lines D1, D2, D3, D4, D5, and D6 may be formed of (or defined by portions of) the sixth conductive layer C6. The data lines D1, D2, D3, D4, D5, and D6 may be electrically connected to one end of the horizontal bridge lines BRH1, BRH2, and BRH3 through the second contact hole CH2 defined or formed through the fifth and sixth insulating layers INS5 and INS6, respectively.

The vertical bridge lines BRV1, BRV2, and BRV3 may be disposed in the same layer as the vertical connection lines CNV1, CNV2, and CNV3. In an embodiment, for example, the vertical bridge lines BRV1, BRV2, and BRV3 may be formed of (or defined by portions of) the sixth conductive layer C6. One end of the vertical bridge lines BRV1, BRV2, and BRV3 may be electrically connected to the second lines LP2 through the second contact portion CNT2 defined or formed through the third to sixth insulating layers INS3, INS4, INS5, and INS6, respectively. The second lines LP2 may be disposed in the same layer as the first lines LP1. The second lines LP2 may be formed of (or defined by portions of) the second conductive layer C2, but are not necessarily limited thereto. Another end of the vertical bridge lines BRV1, BRV2, and BRV3 may be electrically connected to another end of the horizontal bridge lines BRH1, BRH2, and BRH3 through the first contact hole CH1 defined or formed through the fifth and sixth insulating layers INS5 and INS6.

The horizontal bridge lines BRH1, BRH2, and BRH3 may be formed of (or defined by portions of) the fourth conductive layer C4.

The shielding electrodes SDE may be formed of (or defined by portions of) the fifth conductive layer C5. The shielding electrodes SDE may be disposed between the readout lines RX1, RX2, RX3, RX4, RX5, RX6, and RX7 (or the data lines D1, D2, D3, D4, D5, and D6) and the horizontal connection lines CNH1, CNH2, and CNH3 (or the horizontal bridge lines BRH1, BRH2, and BRH3). Accordingly, as described above, crosstalk may be improved by minimizing the coupling cap that may occur due to overlapping lines.

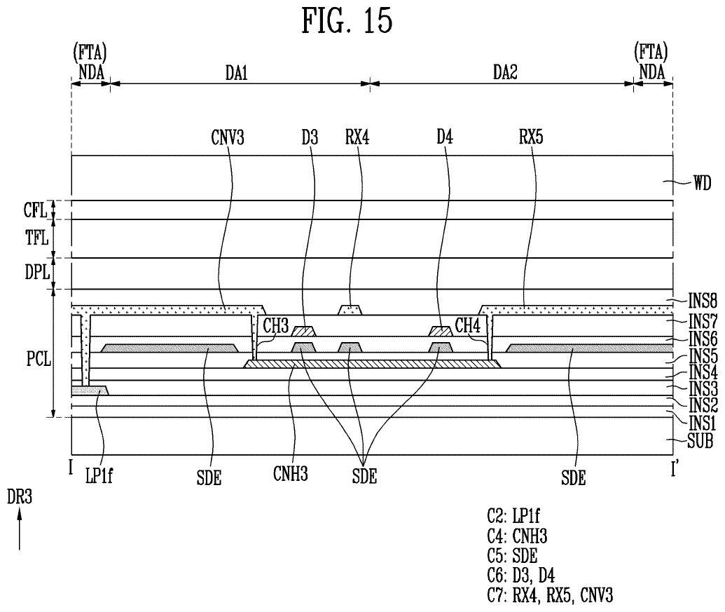

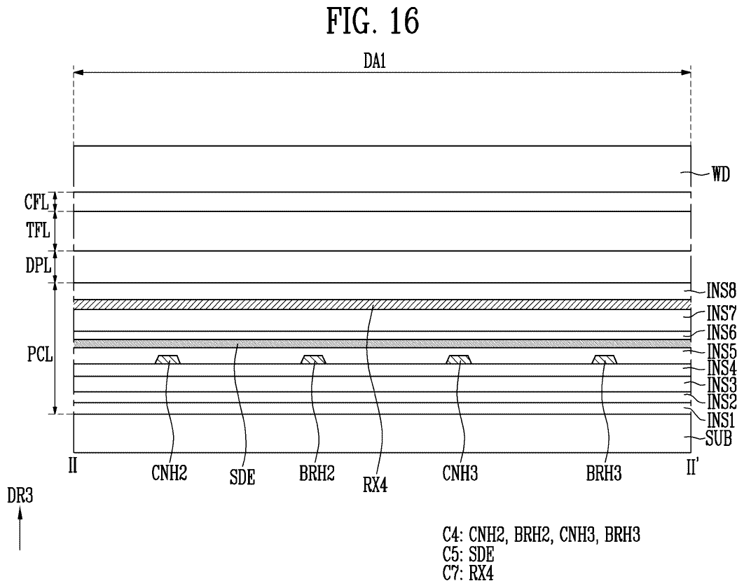

Referring to FIGS. 15 and 16, in another embodiment, the readout lines RX1, RX2, RX3, RX4, RX5, RX6, and RX7 may be formed of (or defined by portions of) the seventh conductive layer C7. The readout lines RX1, RX2, RX3, RX4, RX5, RX6, and RX7 may be electrically connected to one end of the horizontally connection lines CNH1, CNH2, and CNH3 through the fourth contact hole CH4 defined or formed through the fifth to seventh insulating layers INS5, INS6, and INS7, respectively.

The vertical connection lines CNV1, CNV2, and CNV3 may be formed of (or defined by portions of) the seventh conductive layer C7. One end of the vertical connection lines CNV1, CNV2, and CNV3 may be electrically connected to the first lines LP1 through the first contact portion CNT1 defined or formed through the third to seventh insulating layers INS3, INS4, INS5, INS6, and INS7, respectively. The first lines LP1 may be formed of (or defined by portions of) the second conductive layer C2, but are not necessarily limited thereto. Another end of the vertical connection lines CNV1, CNV2, and CNV3 may be electrically connected to another end of the horizontal connection lines CNH1, CNH2, and CNH3 through the third contact hole CH3 defined or formed through the fifth to seventh insulating layers INS5, INS6, and INS7.

The horizontal connection lines CNH1, CNH2, and CNH3 may be formed of (or defined by portions of) the fourth conductive layer C4.

The data lines D1, D2, D3, D4, D5, and D6 may be formed of (or defined by portions of) the sixth conductive layer C6. The data lines D1, D2, D3, D4, D5, and D6 may be electrically connected to one end of the horizontal bridge lines BRH1, BRH2, and BRH3 through the second contact hole CH2 defined or formed through the fifth and sixth insulating layers INS5 and INS6, respectively.

The vertical bridge lines BRV1, BRV2, and BRV3 may be disposed in the same layer as the vertical connection lines CNV1, CNV2, and CNV3. In an embodiment, for example, the vertical bridge lines BRV1, BRV2, and BRV3 may be formed of (or defined by portions of) the seventh conductive layer C7. One end of the vertical bridge lines BRV1, BRV2, and BRV3 may be electrically connected to the second lines LP2 through the second contact portion CNT2 defined or formed through the third to seventh insulating layers INS3, INS4, INS5, INS6, and INS7, respectively. The second lines LP2 may be disposed in the same layer as the first lines LP1. The second lines LP2 may be formed of (or defined by portions of) the second conductive layer C2, but are not necessarily limited thereto. Another end of the vertical bridge lines BRV1, BRV2, and BRV3 may be electrically connected to another end of the horizontal bridge lines BRH1, BRH2, and BRH3 through the first contact hole CH1 defined or formed through the fifth to seventh insulating layers INS5, INS6, and INS7.

The horizontal bridge lines BRH1, BRH2, and BRH3 may be formed of (or defined by portions of) the fourth conductive layer C4.

The shielding electrodes SDE may be formed of (or defined by portions of) the fifth conductive layer C5. The shielding electrodes SDE may be disposed between the readout lines RX1, RX2, RX3, RX4, RX5, RX6, and RX7 (or the data lines D1, D2, D3, D4, D5, and D6) and the horizontal connection lines CNH1, CNH2, and CNH3 (or the horizontal bridge lines BRH1, BRH2, and BRH3). Accordingly, as described above, crosstalk may be improved by minimizing the coupling cap that may occur due to overlapping lines.

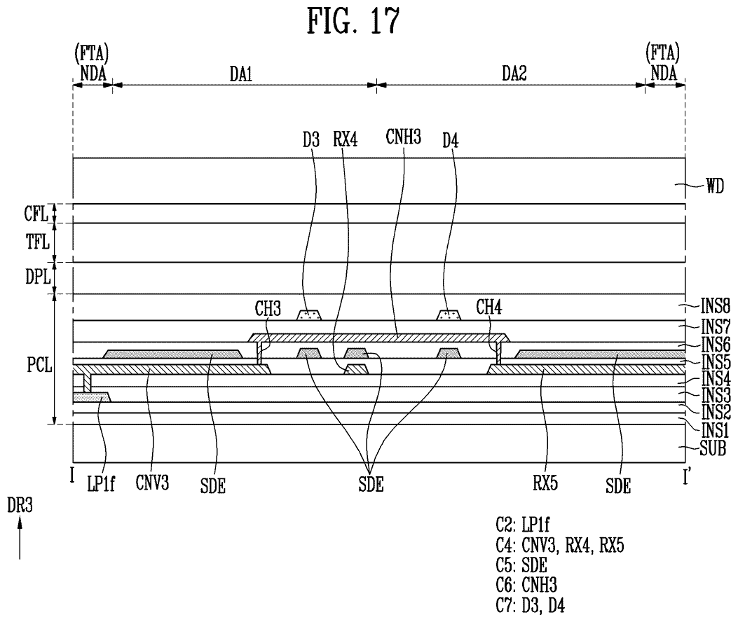

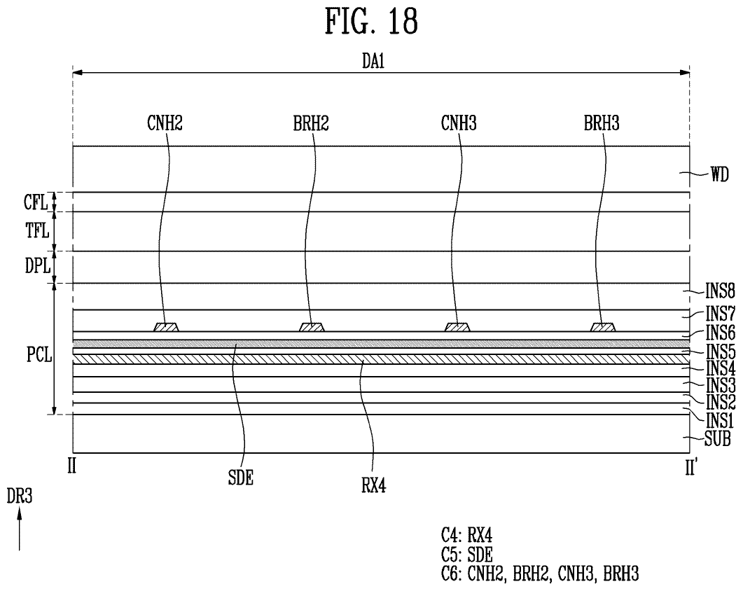

Referring to FIGS. 17 and 18, in another embodiment, the readout lines RX1, RX2, RX3, RX4, RX5, RX6, and RX7 may be formed of (or defined by portions of) the fourth conductive layer C4. The readout lines RX1, RX2, RX3, RX4, RX5, RX6, and RX7 may be electrically connected to one end of the horizontally connection lines CNH1, CNH2, and CNH3 through the fourth contact hole CH4 defined or formed through the fifth and sixth insulating layers INS5 and INS6, respectively.

The vertical connection lines CNV1, CNV2, and CNV3 may be formed of (or defined by portions of) the fourth conductive layer C4. One end of the vertical connection lines CNV1, CNV2, and CNV3 may be electrically connected to the first lines LP1 through the first contact portion CNT1 defined or formed through the third and fourth insulating layers INS3 and INS4, respectively. The first lines LP1 may be formed of (or defined by portions of) the second conductive layer C2, but are not necessarily limited thereto. Another end of the vertical connection lines CNV1, CNV2, and CNV3 may be electrically connected to another end of the horizontal connection lines CNH1, CNH2, and CNH3 through the third contact hole CH3 defined or formed through the fifth and sixth insulating layers INS5 and INS6.

The horizontal connection lines CNH1, CNH2, and CNH3 may be formed of (or defined by portions of) the sixth conductive layer C6.

The data lines D1, D2, D3, D4, D5, and D6 may be formed of (or defined by portions of) the seventh conductive layer C7. The data lines D1, D2, D3, D4, D5, and D6 may be electrically connected to one end of the horizontal bridge lines BRH1, BRH2, and BRH3 through the second contact hole CH2 defined or formed through the seventh insulating layer INS7, respectively.

The vertical bridge lines BRV1, BRV2, and BRV3 may be disposed in the same layer as the vertical connection lines CNV1, CNV2, and CNV3. In an embodiment, for example, the vertical bridge lines BRV1, BRV2, and BRV3 may be formed of (or defined by portions of) the fourth conductive layer C4. One end of the vertical bridge lines BRV1, BRV2, and BRV3 may be electrically connected to the second lines LP2 through the second contact portion CNT2 defined or formed through the third and fourth insulating layers INS3 and INS4, respectively. The second lines LP2 may be disposed in the same layer as the first lines LP1. The second lines LP2 may be formed of (or defined by portions of) the second conductive layer C2, but are not necessarily limited thereto. Another end of the vertical bridge lines BRV1, BRV2, and BRV3 may be electrically connected to another end of the horizontal bridge lines BRH1, BRH2, and BRH3 through the first contact hole CH1 defined or formed through the fifth and sixth insulating layers INS5 and INS6.

The horizontal bridge lines BRH1, BRH2, and BRH3 may be formed of (or defined by portions of) the sixth conductive layer C6.

The shielding electrodes SDE may be formed of (or defined by portions of) the fifth conductive layer C5. The shielding electrodes SDE may be disposed between the readout lines RX1, RX2, RX3, RX4, RX5, RX6, and RX7 and the horizontal connection lines CNH1, CNH2, and CNH3 (or the horizontal bridge lines BRH1, BRH2, and BRH3). Accordingly, as described above, crosstalk may be improved by minimizing the coupling cap that may occur due to overlapping lines.

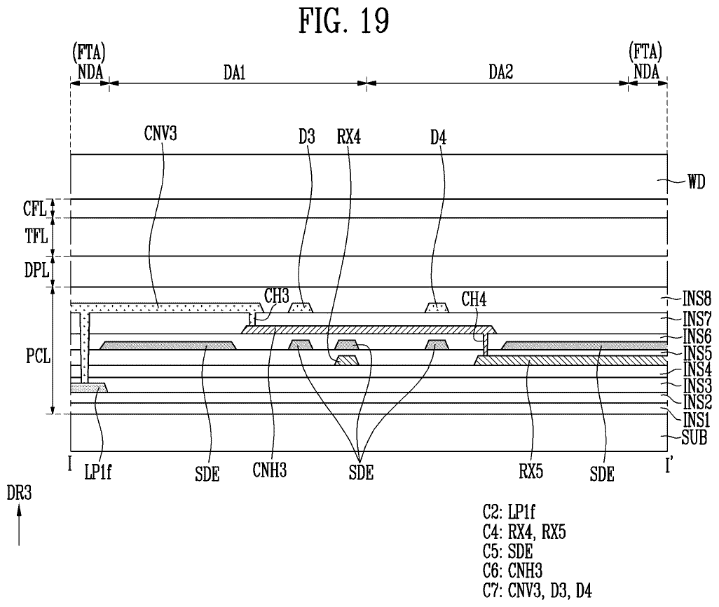

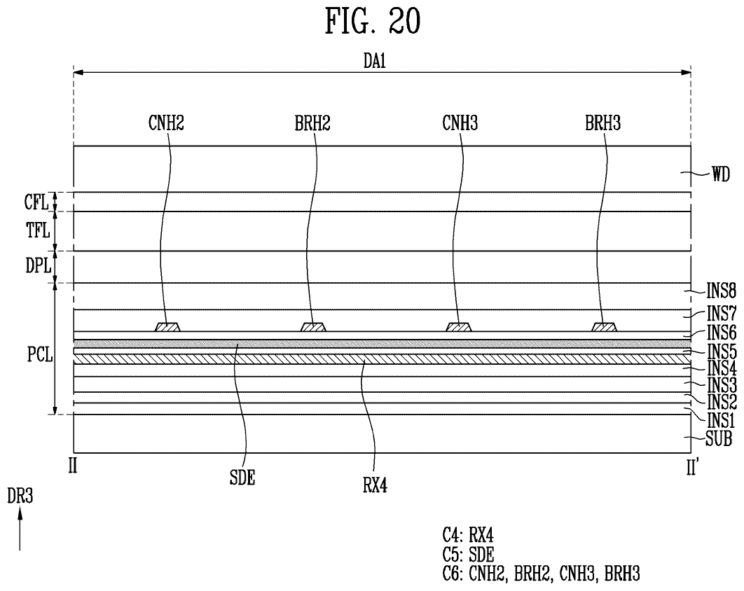

Referring to FIGS. 19 and 20, in another embodiment, the readout lines RX1, RX2, RX3, RX4, RX5, RX6, and RX7 may be formed of (or defined by portions of) the fourth conductive layer C4. The readout lines RX1, RX2, RX3, RX4, RX5, RX6, and RX7 may be electrically connected to one end of the horizontally connection lines CNH1, CNH2, and CNH3 through the fourth contact hole CH4 defined or formed through the fifth and sixth insulating layers INS5 and INS6, respectively.

The vertical connection lines CNV1, CNV2, and CNV3 may be formed of (or defined by portions of) the seventh conductive layer C7. One end of the vertical connection lines CNV1, CNV2, and CNV3 may be electrically connected to the first lines LP1 through the first contact portion CNT1 defined or formed through the third to seventh insulating layers INS3, INS4, INS5, INS6, and INS7, respectively. The first lines LP1 may be formed of (or defined by portions of) the second conductive layer C2, but are not necessarily limited thereto. Another end of the vertical connection lines CNV1, CNV2, and CNV3 may be electrically connected to another end of the horizontal connection lines CNH1, CNH2, and CNH3 through the third contact hole CH3 defined or formed through the seventh insulating layer INS7.

The horizontal connection lines CNH1, CNH2, and CNH3 may be formed of (or defined by portions of) the sixth conductive layer C6.

The data lines D1, D2, D3, D4, D5, and D6 may be formed of (or defined by portions of) the seventh conductive layer C7. The data lines D1, D2, D3, D4, D5, and D6 may be electrically connected to one end of the horizontal bridge lines BRH1, BRH2, and BRH3 through the second contact hole CH2 defined or formed through the seventh insulating layer INS7, respectively.

The vertical bridge lines BRV1, BRV2, and BRV3 may be disposed in the same layer as the vertical connection lines CNV1, CNV2, and CNV3. In an embodiment, for example, the vertical bridge lines BRV1, BRV2, and BRV3 may be formed of (or defined by portions of) the seventh conductive layer C7. One end of the vertical bridge lines BRV1, BRV2, and BRV3 may be electrically connected to the second lines LP2 through the second contact portion CNT2 defined or formed through the third to seventh insulating layers INS3, INS4, INS5, INS6, and INS7, respectively. The second lines LP2 may be disposed in the same layer as the first lines LP1. The second lines LP2 may be formed of (or defined by portions of) the second conductive layer C2, but are not necessarily limited thereto. Another end of the vertical bridge lines BRV1, BRV2, and BRV3 may be electrically connected to another end of the horizontal bridge lines BRH1, BRH2, and BRH3 through the first contact hole CH1 defined or formed through the seventh insulating layer INS7.

The horizontal bridge lines BRH1, BRH2, and BRH3 may be formed of (or defined by portions of) the sixth conductive layer C6.

The shielding electrodes SDE may be formed of (or defined by portions of) the fifth conductive layer C5. The shielding electrodes SDE may be disposed between the readout lines RX1, RX2, RX3, RX4, RX5, RX6, and RX7 and the horizontal connection lines CNH1, CNH2, and CNH3 (or the horizontal bridge lines BRH1, BRH2, and BRH3). Accordingly, as described above, crosstalk may be improved by minimizing the coupling cap that may occur due to overlapping lines.

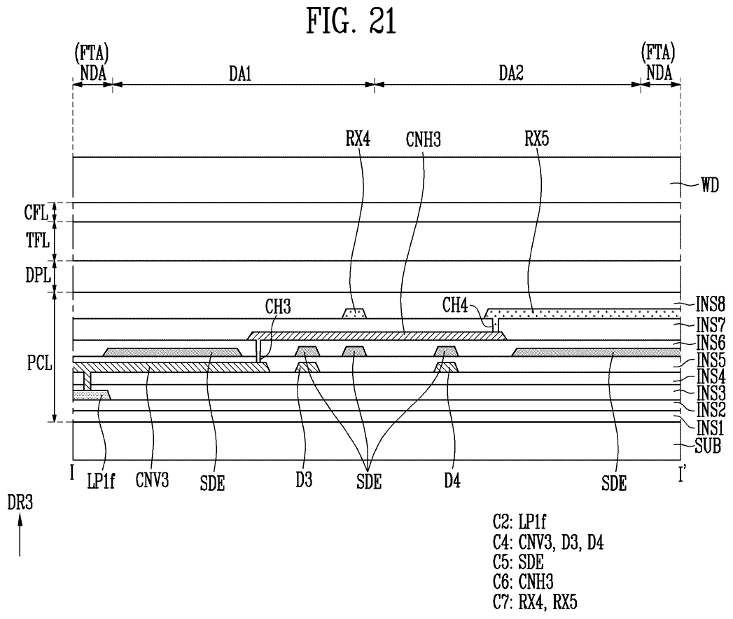

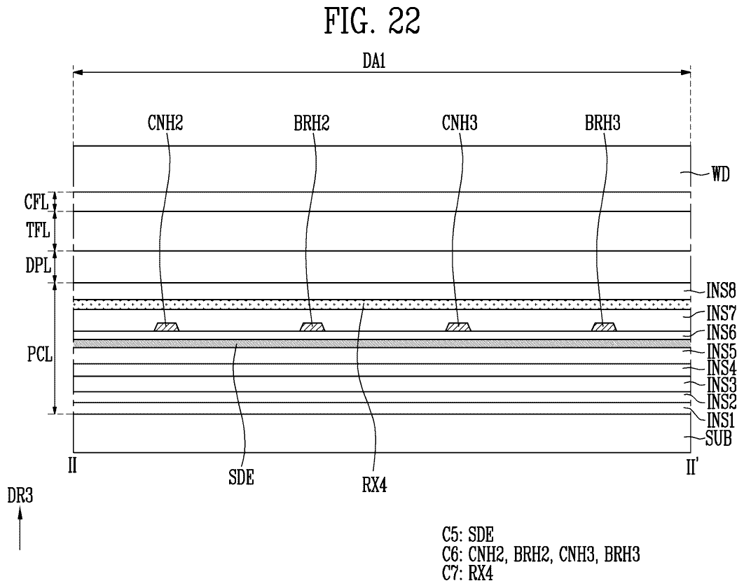

Referring to FIGS. 21 and 22, in another embodiment, the readout lines RX1, RX2, RX3, RX4, RX5, RX6, and RX7 may be formed of (or defined by portions of) the seventh conductive layer C7. The readout lines RX1, RX2, RX3, RX4, RX5, RX6, and RX7 may be electrically connected to one end of the horizontally connection lines CNH1, CNH2, and CNH3 through the fourth contact hole CH4 defined or formed through the seventh insulating layer INS7, respectively.

The vertical connection lines CNV1, CNV2, and CNV3 may be formed of (or defined by portions of) the fourth conductive layer C4. One end of the vertical connection lines CNV1, CNV2, and CNV3 may be electrically connected to the first lines LP1 through the first contact portion CNT1 defined or formed through the third and fourth insulating layers INS3 and INS4, respectively. The first lines LP1 may be formed of (or defined by portions of) the second conductive layer C2, but are not necessarily limited thereto. Another end of the vertical connection lines CNV1, CNV2, and CNV3 may be electrically connected to another end of the horizontal connection lines CNH1, CNH2, and CNH3 through the third contact hole CH3 defined or formed through the fifth and sixth insulating layers INS5 and INS6.

The horizontal connection lines CNH1, CNH2, and CNH3 may be formed of (or defined by portions of) the sixth conductive layer C6.

The data lines D1, D2, D3, D4, D5, and D6 may be formed of (or defined by portions of) the fourth conductive layer C4. The data lines D1, D2, D3, D4, D5, and D6 may be electrically connected to one end of the horizontal bridge lines BRH1, BRH2, and BRH3 through the second contact hole CH2 defined or formed through the fifth and sixth insulating layer INS5 and INS6, respectively.

The vertical bridge lines BRV1, BRV2, and BRV3 may be disposed in the same layer as the vertical connection lines CNV1, CNV2, and CNV3. In an embodiment, for example, the vertical bridge lines BRV1, BRV2, and BRV3 may be formed of (or defined by portions of) the fourth conductive layer C4. One end of the vertical bridge lines BRV1, BRV2, and BRV3 may be electrically connected to the second lines LP2 through the second contact portion CNT2 defined or formed through the third and fourth insulating layers INS3 and INS4, respectively. The second lines LP2 may be disposed in the same layer as the first lines LP1. The second lines LP2 may be formed of (or defined by portions of) the second conductive layer C2, but are not necessarily limited thereto. Another end of the vertical bridge lines BRV1, BRV2, and BRV3 may be electrically connected to another end of the horizontal bridge lines BRH1, BRH2, and BRH3 through the first contact hole CH1 defined or formed through the fifth and sixth insulating layers INS5 and INS6.

The horizontal bridge lines BRH1, BRH2, and BRH3 may be formed of (or defined by portions of) the sixth conductive layer C6.

The shielding electrodes SDE may be formed of (or defined by portions of) the fifth conductive layer C5. The shielding electrodes SDE may be disposed between the data lines D1, D2, D3, D4, D5, and D6 and the horizontal connection lines CNH1, CNH2, and CNH3 (or the horizontal bridge lines BRH1, BRH2, and BRH3). Accordingly, as described above, crosstalk may be improved by minimizing the coupling cap that may occur due to overlapping lines.

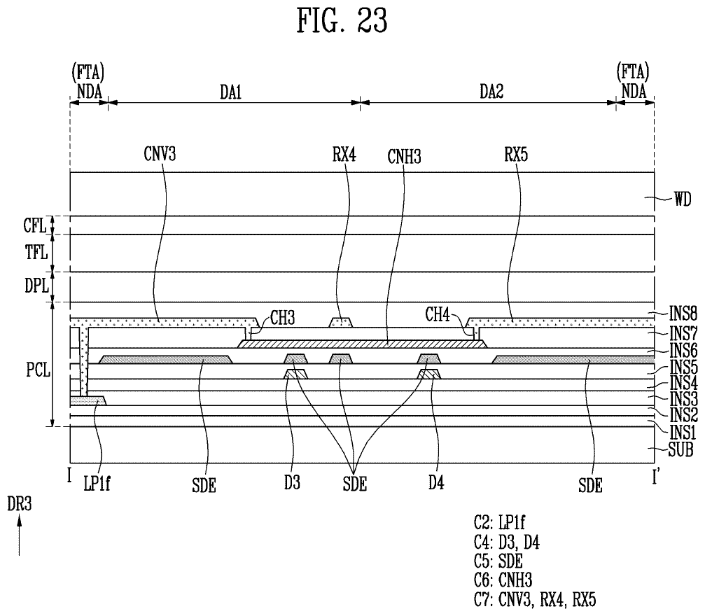

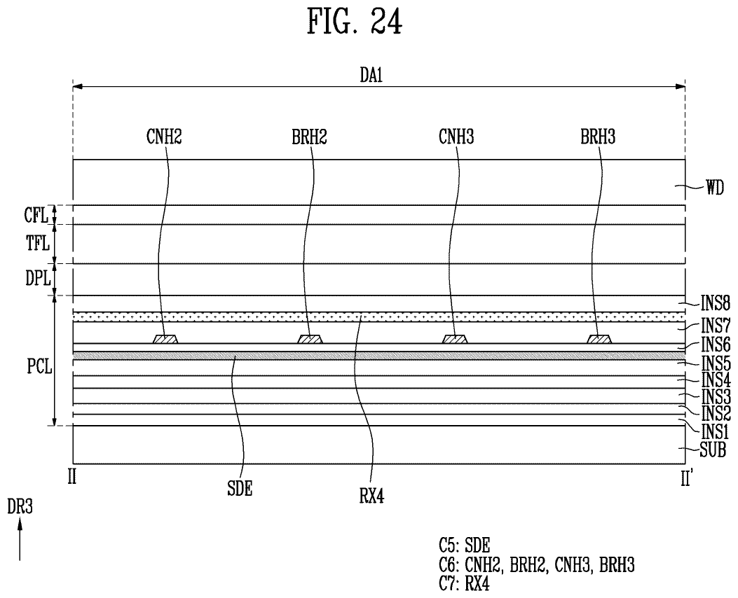

Referring to FIGS. 23 and 24, in another embodiment, the readout lines RX1, RX2, RX3, RX4, RX5, RX6, and RX7 may be formed of (or defined by portions of) the seventh conductive layer C7. The readout lines RX1, RX2, RX3, RX4, RX5, RX6, and RX7 may be electrically connected to one end of the horizontally connection lines CNH1, CNH2, and CNH3 through the fourth contact hole CH4 defined or formed through the seventh insulating layer INS7, respectively.

The vertical connection lines CNV1, CNV2, and CNV3 may be formed of (or defined by portions of) the seventh conductive layer C7. One end of the vertical connection lines CNV1, CNV2, and CNV3 may be electrically connected to the first lines LP1 through the first contact portion CNT1 defined or formed through the third to seventh insulating layers INS3, INS4, INS5, INS6, and INS7, respectively. The first lines LP1 may be formed of (or defined by portions of) the second conductive layer C2, but are not necessarily limited thereto. Another end of the vertical connection lines CNV1, CNV2, and CNV3 may be electrically connected to another end of the horizontal connection lines CNH1, CNH2, and CNH3 through the third contact hole CH3 defined or formed through the seventh insulating layer INS7.

The horizontal connection lines CNH1, CNH2, and CNH3 may be formed of (or defined by portions of) the sixth conductive layer C6.

The data lines D1, D2, D3, D4, D5, and D6 may be formed of (or defined by portions of) the fourth conductive layer C4. The data lines D1, D2, D3, D4, D5, and D6 may be electrically connected to one end of the horizontal bridge lines BRH1, BRH2, and BRH3 through the second contact hole CH2 defined or formed through the fifth and sixth insulating layer INS5 and INS6, respectively.

The vertical bridge lines BRV1, BRV2, and BRV3 may be disposed in the same layer as the vertical connection lines CNV1, CNV2, and CNV3. In an embodiment, for example, the vertical bridge lines BRV1, BRV2, and BRV3 may be formed of (or defined by portions of) the seventh conductive layer C7. One end of the vertical bridge lines BRV1, BRV2, and BRV3 may be electrically connected to the second lines LP2 through the second contact portion CNT2 defined or formed through the third to seventh insulating layers INS3, INS4, INS5, INS6, and INS7, respectively. The second lines LP2 may be disposed in the same layer as the first lines LP1. The second lines LP2 may be formed of (or defined by portions of) the second conductive layer C2, but are not necessarily limited thereto. Another end of the vertical bridge lines BRV1, BRV2, and BRV3 may be electrically connected to another end of the horizontal bridge lines BRH1, BRH2, and BRH3 through the first contact hole CH1 defined or formed through the seventh insulating layer INS7.

The horizontal bridge lines BRH1, BRH2, and BRH3 may be formed of (or defined by portions of) the sixth conductive layer C6.

The shielding electrodes SDE may be formed of (or defined by portions of) the fifth conductive layer C5. The shielding electrodes SDE may be disposed between the data lines D1, D2, D3, D4, D5, and D6 and the horizontal connection lines CNH1, CNH2, and CNH3 (or the horizontal bridge lines BRH1, BRH2, and BRH3). Accordingly, as described above, crosstalk may be improved by minimizing the coupling cap that may occur due to overlapping lines.

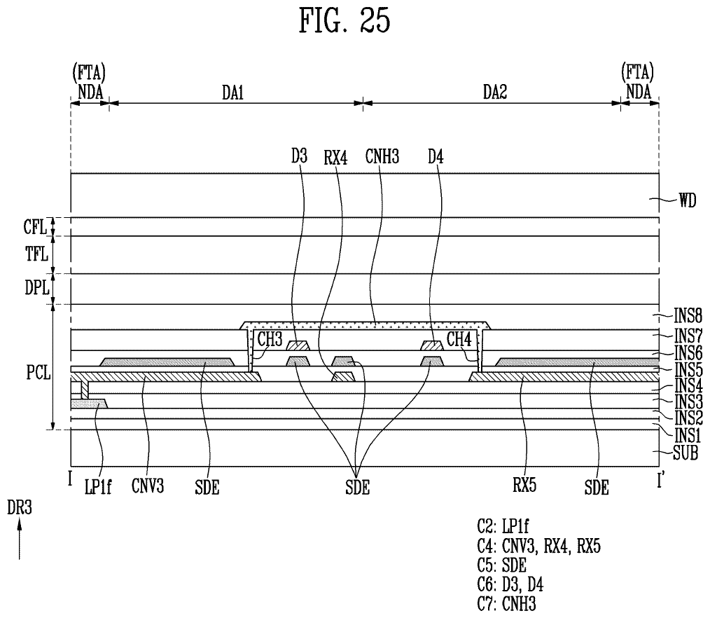

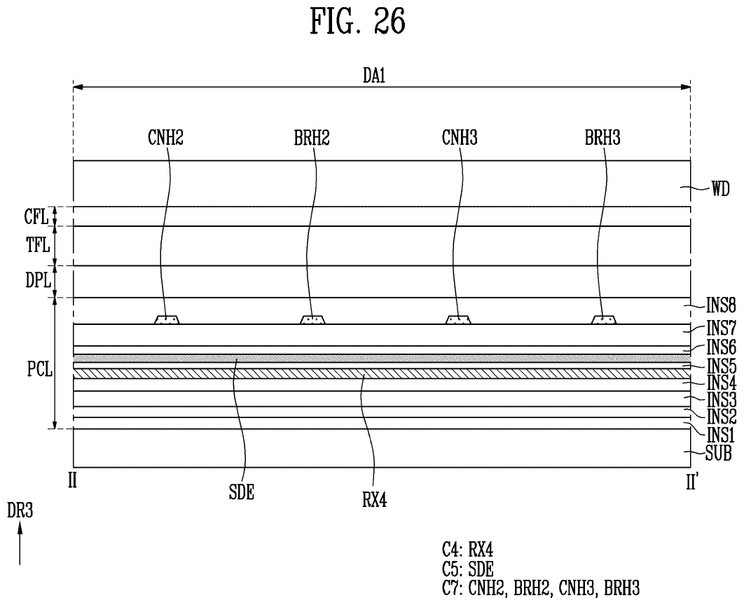

Referring to FIGS. 25 and 26, in another embodiment, the readout lines RX1, RX2, RX3, RX4, RX5, RX6, and RX7 may be formed of (or defined by portions of) the fourth conductive layer C4. The readout lines RX1, RX2, RX3, RX4, RX5, RX6, and RX7 may be electrically connected to one end of the horizontally connection lines CNH1, CNH2, and CNH3 through the fourth contact hole CH4 defined or formed through the fifth to seventh insulating layers INS5, INS6, and INS7, respectively.

The vertical connection lines CNV1, CNV2, and CNV3 may be formed of (or defined by portions of) the fourth conductive layer C4. One end of the vertical connection lines CNV1, CNV2, and CNV3 may be electrically connected to the first lines LP1 through the first contact portion CNT1 defined or formed through the third and fourth insulating layers INS3 and INS4, respectively. The first lines LP1 may be formed of (or defined by portions of) the second conductive layer C2, but are not necessarily limited thereto. Another end of the vertical connection lines CNV1, CNV2, and CNV3 may be electrically connected to another end of the horizontal connection lines CNH1, CNH2, and CNH3 through the third contact hole CH3 defined or formed through the fifth to seventh insulating layers INS5, INS6, and INS7.

The horizontal connection lines CNH1, CNH2, and CNH3 may be formed of (or defined by portions of) the seventh conductive layer C7.

The data lines D1, D2, D3, D4, D5, and D6 may be formed of (or defined by portions of) the sixth conductive layer C6. The data lines D1, D2, D3, D4, D5, and D6 may be electrically connected to one end of the horizontal bridge lines BRH1, BRH2, and BRH3 through the second contact hole CH2 defined or formed through the seventh insulating layer INS7, respectively.

The vertical bridge lines BRV1, BRV2, and BRV3 may be disposed in the same layer as the vertical connection lines CNV1, CNV2, and CNV3. In an embodiment, for example, the vertical bridge lines BRV1, BRV2, and BRV3 may be formed of (or defined by portions of) the fourth conductive layer C4. One end of the vertical bridge lines BRV1, BRV2, and BRV3 may be electrically connected to the second lines LP2 through the second contact portion CNT2 defined or formed through the third and fourth insulating layers INS3 and INS4, respectively. The second lines LP2 may be disposed in the same layer as the first lines LP1. The second lines LP2 may be formed of (or defined by portions of) the second conductive layer C2, but are not necessarily limited thereto. Another end of the vertical bridge lines BRV1, BRV2, and BRV3 may be electrically connected to another end of the horizontal bridge lines BRH1, BRH2, and BRH3 through the first contact hole CH1 defined or formed through the fifth to seventh insulating layers INS5, INS6, and INS7.

The horizontal bridge lines BRH1, BRH2, and BRH3 may be formed of (or defined by portions of) the seventh conductive layer C7.

The shielding electrodes SDE may be formed of (or defined by portions of) the fifth conductive layer C5. The shielding electrodes SDE may be disposed between the readout lines RX1, RX2, RX3, RX4, RX5, RX6, and RX7 and the horizontal connection lines CNH1, CNH2, and CNH3 (or the horizontal bridge lines BRH1, BRH2, and BRH3). Accordingly, as described above, crosstalk may be improved by minimizing the coupling cap that may occur due to overlapping lines.

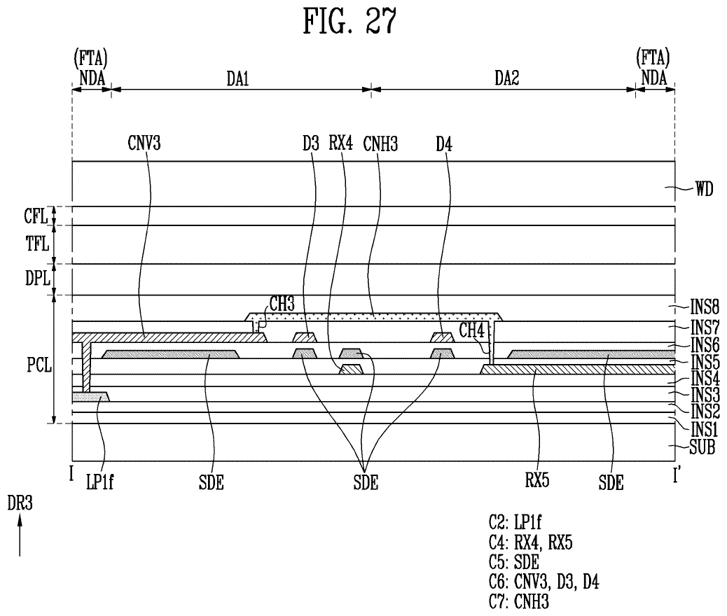

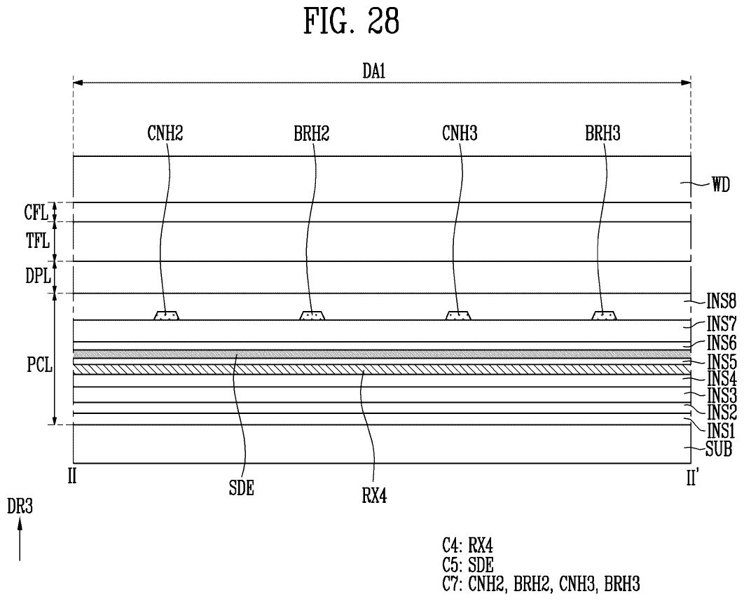

Referring to FIGS. 27 and 28, in another embodiment, the readout lines RX1, RX2, RX3, RX4, RX5, RX6, and RX7 may be formed of (or defined by portions of) the fourth conductive layer C4. The readout lines RX1, RX2, RX3, RX4, RX5, RX6, and RX7 may be electrically connected to one end of the horizontally connection lines CNH1, CNH2, and CNH3 through the fourth contact hole CH4 defined or formed through the fifth to seventh insulating layers INS5, INS6, and INS7, respectively.

The vertical connection lines CNV1, CNV2, and CNV3 may be formed of (or defined by portions of) the sixth conductive layer C6. One end of the vertical connection lines CNV1, CNV2, and CNV3 may be electrically connected to the first lines LP1 through the first contact portion CNT1 defined or formed through the third to sixth insulating layers INS3, INS4, INS5, and INS6, respectively. The first lines LP1 may be formed of (or defined by portions of) the second conductive layer C2, but are not necessarily limited thereto. Another end of the vertical connection lines CNV1, CNV2, and CNV3 may be electrically connected to another end of the horizontal connection lines CNH1, CNH2, and CNH3 through the third contact hole CH3 defined or formed through the seventh insulating layer INS7.

The horizontal connection lines CNH1, CNH2, and CNH3 may be formed of (or defined by portions of) the seventh conductive layer C7.

The data lines D1, D2, D3, D4, D5, and D6 may be formed of (or defined by portions of) the sixth conductive layer C6. The data lines D1, D2, D3, D4, D5, and D6 may be electrically connected to one end of the horizontal bridge lines BRH1, BRH2, and BRH3 through the second contact hole CH2 defined or formed through the seventh insulating layer INS7, respectively.

The vertical bridge lines BRV1, BRV2, and BRV3 may be disposed in the same layer as the vertical connection lines CNV1, CNV2, and CNV3. In an embodiment, for example, the vertical bridge lines BRV1, BRV2, and BRV3 may be formed of (or defined by portions of) the sixth conductive layer C6. One end of the vertical bridge lines BRV1, BRV2, and BRV3 may be electrically connected to the second lines LP2 through the second contact portion CNT2 defined or formed through the third to sixth insulating layers INS3, INS4, INS5, and INS6, respectively. The second lines LP2 may be disposed in the same layer as the first lines LP1. The second lines LP2 may be formed of (or defined by portions of) the second conductive layer C2, but are not necessarily limited thereto. Another end of the vertical bridge lines BRV1, BRV2, and BRV3 may be electrically connected to another end of the horizontal bridge lines BRH1, BRH2, and BRH3 through the first contact hole CH1 defined or formed through the seventh insulating layer INS7.

The horizontal bridge lines BRH1, BRH2, and BRH3 may be formed of (or defined by portions of) the seventh conductive layer C7.

The shielding electrodes SDE may be formed of (or defined by portions of) the fifth conductive layer C5. The shielding electrodes SDE may be disposed between the readout lines RX1, RX2, RX3, RX4, RX5, RX6, and RX7 and the horizontal connection lines CNH1, CNH2, and CNH3 (or the horizontal bridge lines BRH1, BRH2, and BRH3). Accordingly, as described above, crosstalk may be improved by minimizing the coupling cap that may occur due to overlapping lines.

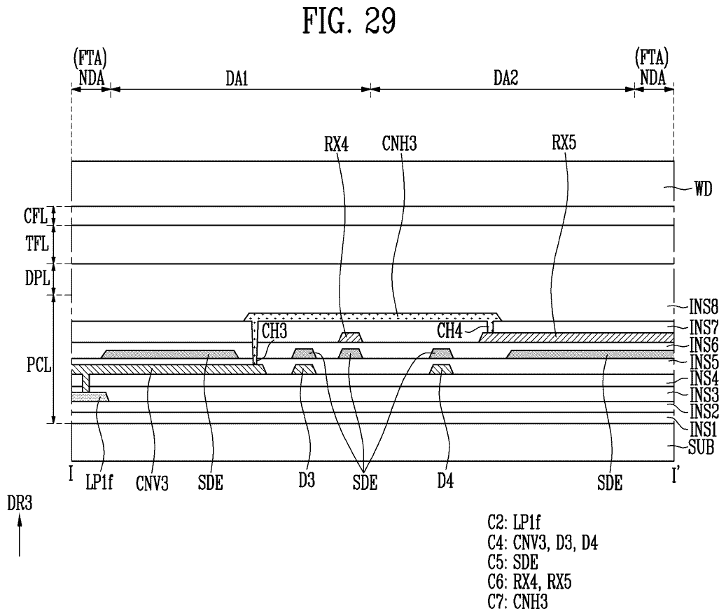

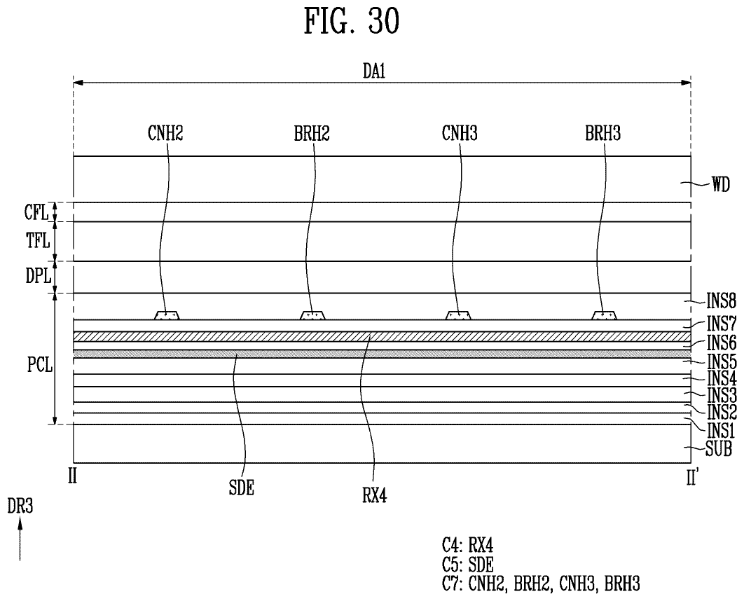

Referring to FIGS. 29 and 30, in another embodiment, the readout lines RX1, RX2, RX3, RX4, RX5, RX6, and RX7 may be formed of (or defined by portions of) the sixth conductive layer C6. The readout lines RX1, RX2, RX3, RX4, RX5, RX6, and RX7 may be electrically connected to one end of the horizontally connection lines CNH1, CNH2, and CNH3 through the fourth contact hole CH4 defined or formed through the seventh insulating layer INS7, respectively.

The vertical connection lines CNV1, CNV2, and CNV3 may be formed of (or defined by portions of) the fourth conductive layer C4. One end of the vertical connection lines CNV1, CNV2, and CNV3 may be electrically connected to the first lines LP1 through the first contact portion CNT1 defined or formed through the third and fourth insulating layers INS3 and INS4, respectively. The first lines LP1 may be formed of (or defined by portions of) the second conductive layer C2, but are not necessarily limited thereto. Another end of the vertical connection lines CNV1, CNV2, and CNV3 may be electrically connected to another end of the horizontal connection lines CNH1, CNH2, and CNH3 through the third contact hole CH3 defined or formed through the fifth to seventh insulating layers INS5, INS6, and INS7.

The horizontal connection lines CNH1, CNH2, and CNH3 may be formed of (or defined by portions of) the seventh conductive layer C7.

The data lines D1, D2, D3, D4, D5, and D6 may be formed of (or defined by portions of) the fourth conductive layer C4. The data lines D1, D2, D3, D4, D5, and D6 may be electrically connected to one end of the horizontal bridge lines BRH1, BRH2, and BRH3 through the second contact hole CH2 defined or formed through the fifth to seventh insulating layers INS5, INS6, and INS7, respectively.

The vertical bridge lines BRV1, BRV2, and BRV3 may be disposed in the same layer as the vertical connection lines CNV1, CNV2, and CNV3. In an embodiment, for example, the vertical bridge lines BRV1, BRV2, and BRV3 may be formed of (or defined by portions of) the fourth conductive layer C4. One end of the vertical bridge lines BRV1, BRV2, and BRV3 may be electrically connected to the second lines LP2 through the second contact portion CNT2 defined or formed through the third and fourth insulating layers INS3 and INS4, respectively. The second lines LP2 may be disposed in the same layer as the first lines LP1. The second lines LP2 may be formed of (or defined by portions of) the second conductive layer C2, but are not necessarily limited thereto. Another end of the vertical bridge lines BRV1, BRV2, and BRV3 may be electrically connected to another end of the horizontal bridge lines BRH1, BRH2, and BRH3 through the first contact hole CH1 defined or formed through the fifth to seventh insulating layers INS5, INS6, and INS7.

The horizontal bridge lines BRH1, BRH2, and BRH3 may be formed of (or defined by portions of) the seventh conductive layer C7.

The shielding electrodes SDE may be formed of (or defined by portions of) the fifth conductive layer C5. The shielding electrodes SDE may be disposed between the data lines D1, D2, D3, D4, D5, and D6 and the horizontal connection lines CNH1, CNH2, and CNH3 (or the horizontal bridge lines BRH1, BRH2, and BRH3). Accordingly, as described above, crosstalk may be improved by minimizing the coupling cap that may occur due to overlapping lines.

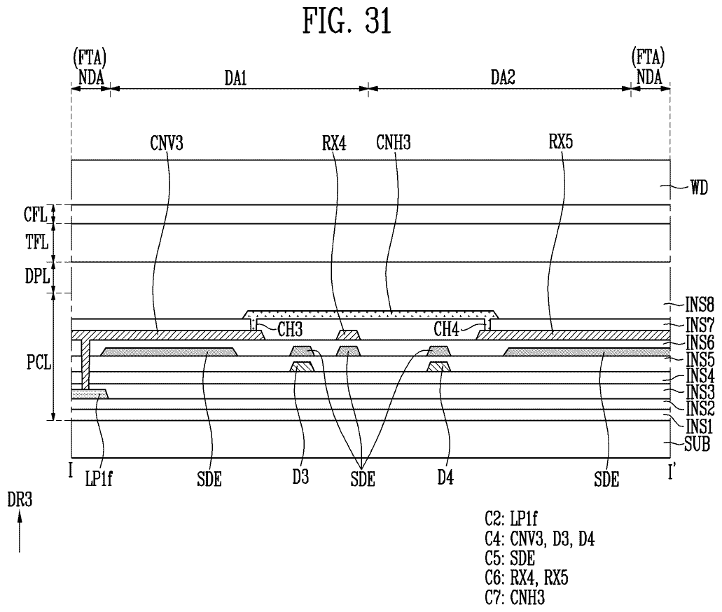

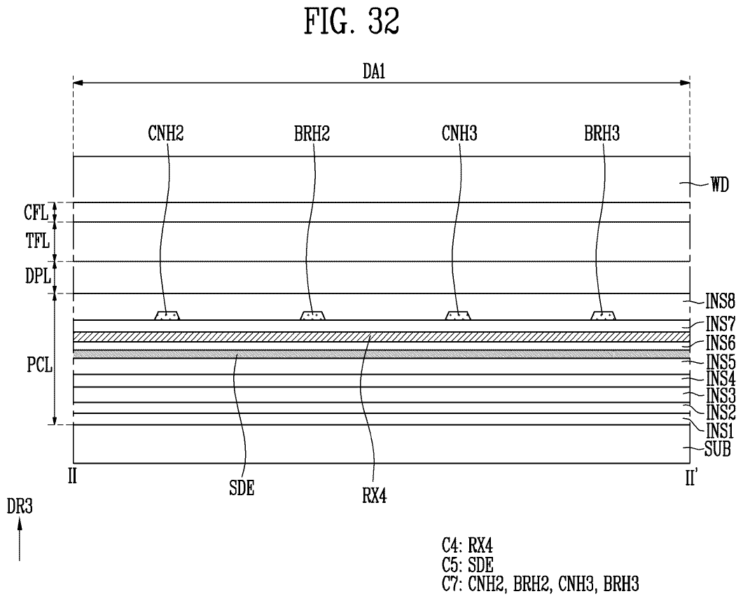

Referring to FIGS. 31 and 32, in another embodiment, the readout lines RX1, RX2, RX3, RX4, RX5, RX6, and RX7 may be formed of (or defined by portions of) the sixth conductive layer C6. The readout lines RX1, RX2, RX3, RX4, RX5, RX6, and RX7 may be electrically connected to one end of the horizontally connection lines CNH1, CNH2, and CNH3 through the fourth contact hole CH4 defined or formed through the seventh insulating layer INS7, respectively.

The vertical connection lines CNV1, CNV2, and CNV3 may be formed of (or defined by portions of) the sixth conductive layer C6. One end of the vertical connection lines CNV1, CNV2, and CNV3 may be electrically connected to the first lines LP1 through the first contact portion CNT1 defined or formed through the third to sixth insulating layers INS3, INS4, INS5, and INS6, respectively. The first lines LP1 may be formed of (or defined by portions of) the second conductive layer C2, but are not necessarily limited thereto. Another end of the vertical connection lines CNV1, CNV2, and CNV3 may be electrically connected to another end of the horizontal connection lines CNH1, CNH2, and CNH3 through the third contact hole CH3 defined or formed through the seventh insulating layer INS7.

The horizontal connection lines CNH1, CNH2, and CNH3 may be formed of (or defined by portions of) the seventh conductive layer C7. The data lines D1, D2, D3, D4, D5, and D6 may be formed of (or defined by portions of) the fourth conductive layer C4. The data lines D1, D2, D3, D4, D5, and D6 may be electrically connected to one end of the horizontal bridge lines BRH1, BRH2, and BRH3 through the second contact hole CH2 defined or formed through the fifth to seventh insulating layers INS5, INS6, and INS7, respectively.

The vertical bridge lines BRV1, BRV2, and BRV3 may be disposed in the same layer as the vertical connection lines CNV1, CNV2, and CNV3. In an embodiment, for example, the vertical bridge lines BRV1, BRV2, and BRV3 may be formed of (or defined by portions of) the sixth conductive layer C6. One end of the vertical bridge lines BRV1, BRV2, and BRV3 may be electrically connected to the second lines LP2 through the second contact portion CNT2 defined or formed through the third to sixth insulating layers INS3, INS4, INS5, and INS6, respectively. The second lines LP2 may be disposed in the same layer as the first lines LP1. The second lines LP2 may be formed of (or defined by portions of) the second conductive layer C2, but are not necessarily limited thereto. Another end of the vertical bridge lines BRV1, BRV2, and BRV3 may be electrically connected to another end of the horizontal bridge lines BRH1, BRH2, and BRH3 through the first contact hole CH1 defined or formed through the seventh insulating layer INS7.

The horizontal bridge lines BRH1, BRH2, and BRH3 may be formed of (or defined by portions of) the seventh conductive layer C7.

The shielding electrodes SDE may be formed of (or defined by portions of) the fifth conductive layer C5. The shielding electrodes SDE may be disposed between the data lines D1, D2, D3, D4, D5, and D6 and the horizontal connection lines CNH1, CNH2, and CNH3 (or the horizontal bridge lines BRH1, BRH2, and BRH3). Accordingly, as described above, crosstalk may be improved by minimizing the coupling cap that may occur due to overlapping lines.

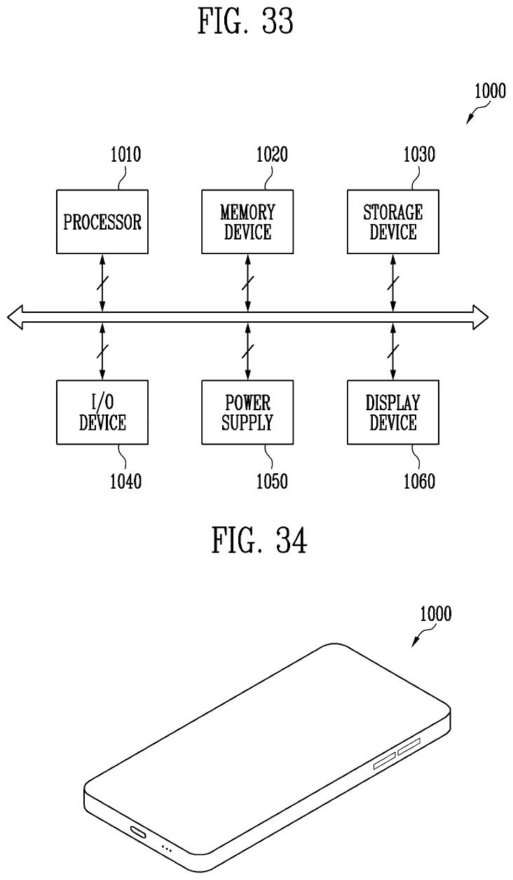

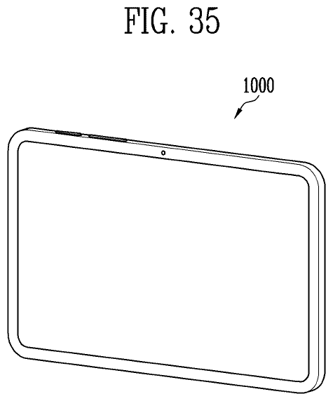

FIG. 33 is a schematic block diagram illustrating an electronic device 1000 including a display device in accordance with an embodiment. FIG. 34 is a schematic diagram illustrating an example where the electronic device 1000 of FIG. 33 is a smartphone. FIG. 35 is a schematic diagram illustrating an example where the electronic device 1000 of FIG. 33 is a tablet computer.

Referring to FIGS. 33 to 35, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 34, the electronic device 1000 may be a smartphone. In an embodiment, as illustrated in FIG. 35, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a display area including a first area and a second area, and a non-display area;
first signal lines disposed on the first area and the second area of the substrate;
first connection lines extending from the first area to the second area, wherein each of the first connection lines is electrically connected to a corresponding one of the first signal lines disposed in the second area;
second connection lines disposed in the first area, wherein each of the second connection lines is electrically connected to a corresponding one of the first connection lines; and
shielding electrodes disposed between the first signal lines and the first connection lines.

2. The display device according to claim 1, wherein the first connection lines are disposed between the substrate and the first signal lines.

3. The display device according to claim 1, wherein the first signal lines and the second connection lines are disposed in a same layer as each other.

4. The display device according to claim 1, wherein the shielding electrodes overlap the first signal lines, respectively, in a thickness direction of the substrate.

5. The display device according to claim 1, wherein the first connection lines extend in a first direction, and
the second connection lines extend in a second direction crossing the first direction.

6. The display device according to claim 5, wherein the first signal lines extend in the second direction.

7. The display device according to claim 5, wherein the shielding electrodes extend in the second direction.

8. The display device according to claim 1, further comprising:
second signal lines spaced apart from the first signal lines.

9. The display device according to claim 8, further comprising:
first bridge lines extending from the second area to the first area, wherein each of the first bridge lines is electrically connected to a corresponding one of the second signal lines disposed in the first area.

10. The display device according to claim 9, further comprising:
second bridge lines disposed in the second area, wherein each of the second bridge lines is electrically connected to a corresponding one of the first bridge lines.

11. A display device comprising:
a substrate including a display area including a first area and a second area, and a non-display area;
first signal lines disposed on the first area and the second area of the substrate;
second signal lines disposed on the first area and the second area of the substrate and spaced apart from the first signal lines;
first connection lines extending from the first area to the second area, wherein each of the first connection lines is electrically connected to a corresponding one of the first signal lines disposed in the second area; and
second connection lines disposed in the first area, wherein each of the second connection lines is electrically connected to a corresponding one of the first connection lines,
wherein
the first signal lines are defined by portions of a first conductive layer,
the second signal lines are defined by portions of a second conductive layer, and
shielding electrodes are disposed between the first conductive layer and the second conductive layer.

12. The display device according to claim 11, wherein the second connection lines are defined by portions of the first conductive layer.

13. The display device according to claim 11, wherein the second connection lines are defined by portions of the second conductive layer.

14. The display device according to claim 11, wherein the first connection lines are defined by portions of a third conductive layer disposed on the first conductive layer and the second conductive layer.

15. The display device according to claim 11, wherein the first connection lines extend in a first direction, and
the second connection lines extend in a second direction crossing the first direction.

16. The display device according to claim 15, wherein the first signal lines and the second signal lines extend in the second direction.

17. The display device according to claim 15, wherein the shielding electrodes extend in the second direction.

18. The display device according to claim 11, further comprising:
first bridge lines extending from the second area to the first area, wherein each of the first bridge lines is electrically connected to a corresponding one of the second signal lines disposed in the first area.

19. The display device according to claim 18, further comprising:
second bridge lines disposed in the second area, wherein each of the second bridge lines is electrically connected to a corresponding one of the first bridge lines.

20. An electronic device comprising:
a processor to provide input image data; and
a display device to display an image based on the input image data, the display device including sub-pixel areas,
wherein the display device comprises:
a substrate including a display area including a first area and a second area, and a non-display area;
first signal lines disposed on the first area and the second area of the substrate;
first connection lines extending from the first area to the second area, wherein each of the first connection lines is electrically connected to a corresponding one of the first signal lines disposed in the second area;
second connection lines disposed in the first area, wherein each of the second connection lines is electrically connected to a corresponding one of the first connection lines; and
shielding electrodes disposed between the first signal lines and the first connection lines.
